(19) United States
(12) Patent Application Publication
(10) Pub. No.: US 2008/0274423 A1
(43) Pub. Date: Nov. 6, 2008

(54) OPTICAL INFORMATION RECORDING MEDIUM AND METHOD OF RECORDING INFORMATION

(75) Inventors: Tatsuo Mikami, Kanagawa (JP); Kazumi Nii, Kanagawa (JP); Shuji Kanayama, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/111,278

(22) Filed: Apr. 29, 2008

(30) Foreign Application Priority Data
May 2, 2007 (JP) 121861/2007

(51) Int. Cl. G03F 7/004

(52) U.S. Cl. 430/270.18

(57) ABSTRACT

The optical information recording medium comprises a recording layer on a support, wherein the recording layer comprises a dye having a film-softening temperature of equal to or higher than 290° C.

### CROSS-REFERENCE TO RELATED APPLICATIONS

This application claims the benefit of priority under 35 USC 119 to Japanese Patent Application No. 2007-121861 filed on May 2, 2007, which is expressly incorporated herein by reference in its entirety.

### BACKGROUND OF THE INVENTION

1. Field of the Invention

The present invention relates to an optical information recording medium, and more particularly, to a heat mode optical information recording medium such as a recordable digital versatile disk (DVD-R) on which information is recorded with a visible laser beam.

2. Discussion of the Background

Optical recording media (optical disks) permitting the one-time recording of information by a laser beam have been known. Such optical disks are also known as recordable CDs (the so-called “CD-R”). In a typical configuration, there is a transparent disk-shaped support on which are sequentially provided a recording layer comprising an organic dye, a reflective layer comprised of a metal such as gold, and a protective layer of resin in a layered state. Information is recorded on a CD-R by irradiating the CD-R with a laser beam in the near infrared region (normally a laser beam with a wavelength in the vicinity of 780 nm). The irradiated portion in the recording layer absorbs the beam, causing a localized rise in temperature and producing a physical or chemical change to form a pit as the formation, thereby changing the optical characteristics to record information. Information is read (reproduced) by irradiating a laser beam of the same wavelength as that employed in recording and detecting the difference in reflectance between pit portions where pits are formed in the recording layer in which the optical characteristics have changed and non-pit portions in which they have not.

In recent years, there has been demand for optical recording media of higher recording density. In response to such demand, an optical disk known as the recordable digital versatile disk (the so-called “DVD-R”) has been proposed. The DVD-R is configured of two disks, each of which is comprised of a transparent disk-shaped support on which are formed guide grooves (pre-grooves) that are half or less (0.74 to 0.8 micrometer) the width of those of a CD-R for tracking the laser beam being irradiated; a recording layer comprising a dye on the support; normally, a reflective layer on this recording layer; and, as needed, a protective layer; that are bonded together with an adhesive, or one such disk bonded with an adhesive to a similarly shaped disk-like protective support with the recording layer on the inside. Information is recorded on and reproduced from a DVD-R by irradiation of a visible laser beam (normally, a laser beam with a wavelength ranging from 630 to 680 nm), permitting higher density recording than with a CD-R.

For the DVD-R, the demand for high-speed recording has been increasing, and optical recording media designed for high-speed recording have been proposed in recent years. For example, an optical recording medium having a linear recording velocity of 10.5 m/s (equivalent to triple that of a DVD-R) and a recording power of equal to or lower than 14 mW that suppresses thermal interference to an asymmetry β≦0% has been proposed (see, for example, Japanese Unexamined Patent Publication (KOKAI) No. 2002-260227, which is expressly incorporated herein by reference in its entirety). Further, to enhance high-speed recording characteristics, an optical recording medium in which a recording layer is formed with a mixture of a dye having an absorption maximum at a wavelength of 350 to 630 nm and a dye having an absorption maximum at a wavelength of 630 to 900 nm has been proposed (see, for example, Japanese Unexamined Patent Publication (KOKAI) No. 2003-34078, which is expressly incorporated herein by reference in its entirety).

In an optical information recording medium containing a recording layer comprising an organic dye, a laser beam is irradiated to form a pit by degrading or altering the dye in the recording layer. The difference in reflectance between pit portions and non-pit portions is used to read the information. In recent years, attempts have been made to further increase the linear recording velocity for reducing the time required for recording. However, during particularly high-speed recording, heat remaining from the process of forming pits of two adjacent recording pits causes problems by affecting the formation of the pits to each other (called thermal interference). Thermal interference causes problems in that the preceding or subsequent pit decreases or increases in size or undergoes a shift in center position, thereby increasing jitter and compromising recording characteristics.

### SUMMARY OF THE INVENTION

An aspect of the present invention provides for an optical information recording medium exhibiting little thermal interference during high-speed recording and affording good jitter.

We conducted extensive research, resulting in the discovery that by employing a dye with a film-softening temperature of equal to or higher than 290° C. in the recording layer, it was possible to suppress thermal interference during high-speed recording. The present invention was devised on that basis.

An aspect of the present invention relates to an optical information recording medium comprising a recording layer on a support, wherein the recording layer comprises a dye having a film-softening temperature of equal to or higher than 290° C.

The dye may be a dye denoted by general formula (I).

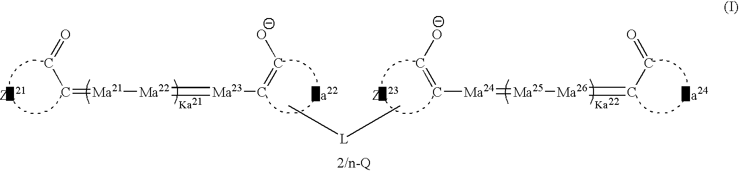

In general formula (I), Za²¹, Za²², Za²³, and Za²⁴ each independently denote an atom group forming an acid nucleus, Ma²¹, Ma²², Ma²³, Ma²⁴, Ma²⁵, and Ma²⁶ each independently denote a substituted or unsubstituted methine group, L denotes a divalent linking group that does not form a π-conjugated system with two bonds, Ka²¹ and Ka²² each independently denote an integer ranging from 0 to 3, and Q denotes a cation of valence n, and n denotes an integer ranging from 1 to 6. When Ka²¹ denotes 2 or 3, plural Ma²¹ and plural Ma²² present may be respectively identical or different from each other; and when Ka²² denotes 2 or 3, plural Ma²⁵ and plural Ma²⁶ present may be respectively identical or different from each other.

Q in general formula (I) may denote a quadrivalent cation denoted by general formula (II).

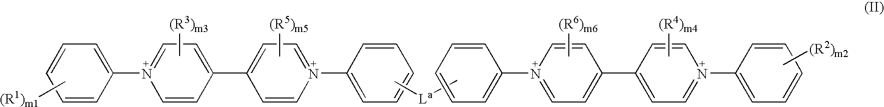

In general formula (II), R¹, R², R³, R⁴, R⁵, and R⁶ each independently denote a substituent, m1 and m2 each independently denote an integer ranging from 0 to 5, m3, m4, m5, and m6 each independently denote an integer ranging from 0 to 4, L^{a} denotes a divalent linking group. When m1 denotes an integer ranging from 2 to 5, plural R¹ present may be identical or different from each other; when m2 denotes an integer ranging from 2 to 5, plural R² present may be identical or different from each other; when m3 denotes an integer ranging from 2 to 4, plural R³ present may be identical or different from each other; when m4 denotes an integer ranging from 2 to 4, plural R⁴ present may be identical or different from each other; when m5 denotes an integer ranging from 2 to 4, plural R⁴ present may be identical or different from each other; and when m6 denotes an integer ranging from 2 to 4, plural R⁶ present may be identical or different from each other.

Q in general formula (I) may denote a divalent cation denoted by general formula (III).

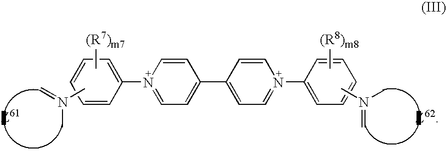

In general formula (III), Z⁶¹ and Z⁶² each independently denote an atom group forming a nitrogen-containing heteroaryl ring, R⁷ and R⁸ each independently denote a substituent, and m7 and m8 each independently denote an integer ranging from 0 to 4. When m7 denotes an integer ranging from 2 to 4, plural R⁷ present may be identical or different from each other; and when m8 denotes in integer ranging from 2 to 4, plural R⁸ present may be identical or different from each other.

The recording layer may satisfy Equation (1) when an EFM signal is recorded in a random pattern at a linear recording velocity of 41.88 m/s:

Average 3T space length/average 14T space length>0.211 (1)

The support may have a pre-groove with a groove depth of equal to or greater than 140 nm on a surface facing the recording layer.

The above optical information recording medium may be a DVD-R optical information recording medium.

In the above optical information recording medium, information may be recorded on the recording layer at a linear recording velocity of equal to or greater than 27.9 m/s.

A further aspect of the present invention relates to a method of recording information on the recording layer comprised in the above optical information recording medium by irradiation of a laser beam onto the optical information recording medium.

In the above method, the information may be recorded at a linear recording velocity of equal to or greater than 27.9 m/s.

The present invention can provide an optical information recording medium affording good recording characteristics and suppressing jitter even during high-speed recording.

Other exemplary embodiments and advantages of the present invention may be ascertained by reviewing the present disclosure.

### DESCRIPTIONS OF THE EMBODIMENTS

The following preferred specific embodiments are, therefore, to be construed as merely illustrative, and non-limiting to the remainder of the disclosure in any way whatsoever. In this regard, no attempt is made to show structural details of the present invention in more detail than is necessary for fundamental understanding of the present invention; the description taken with the drawings making apparent to those skilled in the art how several forms of the present invention may be embodied in practice.

### Optical Information Recording Medium

The optical information recording medium of the present invention will be described in detail below.

The optical information recording medium of the present invention comprises a recording layer comprising a dye having a film-softening temperature of equal to or higher than 290° C. on a support. We have discovered that the increase in jitter due to thermal interference during high speed recording can be suppressed and recording characteristics during high-speed recording by incorporating a dye having a film-softening temperature of equal to or higher than 290° C. into the recording layer. At a film-softening temperature of less than 290° C., thermal interference during high-speed recording causes problems by affecting the formation of two adjacent pits to each other, such as subsequent recording pit to increase in size or undergo a shift in center position, or in some cases causes preceding pit to change in size or undergo a shift in center position as well, thereby increasing jitter and compromising recording characteristics. From the perspective of the ease of forming recording pits, the film-softening temperature is preferably equal to or lower than 400° C. Thus, the dye incorporated into the recording layer preferably has a film-softening temperature ranging from 290 to 400° C., more preferably a film-softening temperature ranging from 330 to 400° C.

In the present invention, the term “film-softening temperature” is a value that is measured by the following method.

### (Measurement Method)

A 20 mg quantity of dye is dissolved in 1 mL of a suitable solvent such as tetrafluoropropanol, the solution is coated on a glass support with a spin coater (coating conditions: room temperature (about 24° C.), rotational speed of 100 rpm) to prepare a coating having a thickness of about 300 nm for the measurement of the film-softening temperature. Next, a model 2990 microthermal analyzer (μTA) made by TA Instruments is used to measure the temperature at which the needle begins to enter the coating film while raising the temperature. This temperature is adopted as the film-softening temperature.

The dye having a film-softening temperature of equal to or higher than 290° C. is preferably a dye denoted by general formula (I) below:

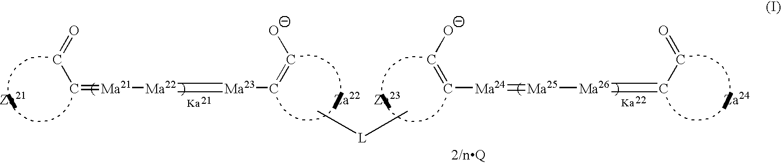

In general formula (I), Za²¹, Za²², Za²³, and Za²⁴ each independently denote an atom group forming an acid nucleus, Ma²¹, Ma²², Ma²³, Ma²⁴, Ma²⁵, and Ma²⁶ each independently denote a substituted or unsubstituted methine group, L denotes a divalent linking group that does not form a π-conjugated system with two bonds, Ka²¹ and Ka²² each independently denote an integer ranging from 0 to 3, and Q denotes a cation of valence n, and n denotes an integer ranging from 1 to 6. When Ka²¹ denotes 2 or 3, plural Ma²¹ and plural Ma²² present may be respectively identical or different from each other; and when Ka²² denotes 2 or 3, plural Ma²⁵ and plural Ma²⁶ present may be respectively identical or different from each other.

It is possible to increase stacking between molecules and thereby achieve a higher film-softening temperature by linking two structures having a π-conjugated system with a linking group L in the dye denoted by general formula (I). Further, linking two structures having a π-conjugated system with a linking group L can increase the maximum absorption wavelength, making it possible to achieve a high refractive index at the recording and reproducing wavelength. A high refractive index permits a reduction in the thickness of the recording layer required to form recording pits, making it possible to suppress the excessive generation of heat during recording.

General formula (I) will be described next.

### General Formula (I)

The dye denoted by general formula (I) comprises a bis-type oxonol anionic moiety and a cationic moiety neutralizing the charge of the anionic moiety. Within the anionic moiety, Za²¹, Za²², Za²³, and Za²⁴ each independently denote an atom group forming an acid nucleus. Examples thereof are described in James, ed., The Theory of the Photographic Process, 4th Ed., Macmillan Corp, 1977, p. 198, which is expressly incorporated herein by reference in its entirety. Specific examples, each of which may be substituted, are nuclei such as pyrazole-5-one, pyrazolidine-3,5-dione, imidazoline-5-one, hydantoin, 2 and 4-thiohydantoin, 2-iminoxyazolidine-4-one, 2-oxazoline-5-one, 2-thiooxazoline-2,4-dione, isorhodanine, rhodanine, thiophene-3-one, thiophene-3-one-1,1-dioxide, indoline-2-one, indoline-3-one, 2-oxoindazolium, 5,7-dioxo-6,7-dihydrothiazolo[3,2-a]pyrimidine, 3,4-dihydroisoquinoline-4-one, 1,3-dioxane-4,6-dione (such as Meldrum's acid), barbituric acid, 2-thiobarbituric acid, coumarin-2,4-dione, indazoline-2-one, pyrido[1,2-a]pyrimidine-1,3-dione, pyrazolo[1,5-b]quinazolone, pyrazolopyridone, and five and six-membered carbon rings (such as hexane-1,3-dione, pentane-1,3-dione, and indole-1,3-dione). Preferable examples are pyrazole-5-one, barbituric acid, 2-thiobarbituric acid, and 1,3-dioxane-4,6-dione. Among these, it is particularly preferable for Za²¹, Za²², Za²³, and Za²⁴, to denote 1,3-dioxane-4,6-dione optionally substituted.

The above acid nucleus may be substituted. Examples of substituents substituting the acid nucleus are: halogen atoms, alkyl groups (including monocyclic and polycyclic alkyl groups such as cycloalkyl groups and bicycloalkyl groups), alkenyl groups (including monocyclic and polycyclic alkenyl groups such as cycloalkenyl groups and bicycloalkenyl groups), alkynyl groups, aryl groups, heterocyclic groups, cyano groups, hydroxyl groups, nitro groups, carboxyl groups, alkoxy groups, aryloxy groups, silyloxy groups, heterocyclic oxy groups, acyloxy groups, carbamoyloxy groups, alkoxycarbonyloxy groups, aryloxycarbonyloxy groups, amino groups (including anilino groups), acylamino groups, aminocarbonylamino groups, alkoxycarbonylamino groups, aryloxycarbonylamino groups, sulfamoylamino groups, alkyl and arylsulfonylamino groups, mercapto groups, alkylthio groups, arylthio groups, heterocyclic thio groups, sulfamoyl groups, sulfo groups, alkyl and arylsulfinyl groups, alkyl and arylsulfonyl groups, acyl groups, aryloxycarbonyl groups, alkoxycarbonyl groups, carbamoyl groups, aryl and heterocyclic azo groups, imido groups, phosphino groups, phosphinyl groups, phosphinyloxy groups, phosphinylamino groups, and silyl groups. Of these, substituted and unsubstituted alkyl groups having 1 to 20 carbon atoms and substituted and unsubstituted aryl groups having 6 to 20 carbon atoms are preferable.

The above acid nucleus is preferably unsubstituted, substituted with a substituted or unsubstituted alkyl group having 1 to 20 carbon atoms, or substituted with a substituted or unsubstituted aryl group having 6 to 20 carbon atoms.

Ma²¹, Ma²², Ma²³, Ma²⁴, Ma²⁵, and Ma²⁶ each independently denote a substituted or unsubstituted methine group. Examples of preferable substituents are alkyl groups having 1 to 20 carbon atoms (such as methyl groups, ethyl groups, and isopropyl groups), halogen atoms (such as chlorine atoms, bromine atoms, iodine atoms, and fluorine atoms), alkoxy groups having 1 to 20 carbon atoms (such as methoxy groups, ethoxy groups, and isopropyl groups), aryl groups having 6 to 26 carbon atoms (such as phenyl groups and 2-naphthyl groups), heterocyclic groups having 0 to 20 carbon atoms (such as 2-pyridyl groups and 3-pyridyl groups), aryloxy groups having 6 to 20 carbon atoms (such as phenoxy groups, 1-naphthoxy groups, and 2-naphthoxy groups), acylamino groups having 1 to 20 carbon atoms (such as acetylamino groups and benzoylamino groups), carbamoyl groups having 1 to 20 carbon atoms (such as N,N-dimethylcarbamoyl groups), sulfo groups, hydroxy groups, carboxy groups, alkylthio groups having 1 to 20 carbon atoms (such as methylthio groups), and cyano groups. They may bond with other methine groups to form a ring structure, and may bond with at least one of the atom groups denoted by Za²¹, Za²², Za²³, and Za²⁴ to form a ring structure.

Each of Ma²¹, Ma²², Ma²³, Ma²⁴, Ma²⁵, and Ma²⁶ preferably independently denotes an unsubstituted methine group or a methine group substituted with a methyl or phenyl group, and particularly preferably denotes an unsubstituted methine group.

L denotes a divalent linking group that does not form a π-conjugated system with two bonds. The linking group denoted by L is not specifically limited other than that a π-conjugated system not be formed between the two chromophores linked by L. L preferably denotes a linking group with 0 to 100 carbon atoms, more preferably 1 to 20 carbon atoms, comprised of one or a combination of two or more members selected from among alkylene groups (preferably alkylene groups having 1 to 20 carbon atoms, such as methylene groups, ethylene groups, propylene groups, butylene groups, and pentylene groups), arylene groups (preferably arylene groups having 6 to 26 carbon atoms, such as phenylene groups and naphthylene groups), alkenylene groups (alkenylene groups having 2 to 20 carbon atoms, such as ethenylene groups and propenylene groups), alkynylene groups (alkynylene groups having 2 to 20 carbon atoms, such as ethynylene groups and propynylene groups); —CO—N(R¹⁰¹)—, —CO—O—, —SO₂—N(R¹⁰²)—, —SO₂—O—, —N(R¹⁰³)—CO—N(R¹⁰⁴)—, —SO₂—, —SO—, —S—, —O—, —CO—, —N(R¹⁰⁵)—, and heterylene groups (heterylene groups having 1 to 26 carbon atoms, such as 6-chloro-1,3,5-triazyl-2,4-diyl groups and pyrimidine-2,4-diyl groups). Each of R¹⁰¹, R¹⁰², R¹⁰³, R¹⁰⁴, and R¹⁰⁵ independently denotes a hydrogen atom, substituted or unsubstituted alkyl group, or substituted or unsubstituted aryl group. One or more linking groups denoted by L may be present between the two chromophores linked by L, and plural (preferably two) of such groups may bond together to form a ring.

Preferable examples of linking group L are two alkylene groups (preferably ethylene groups) bound together to form a ring. Of these, the case where a five or six-membered ring (preferably a cyclohexyl) is formed is further preferable.

In general formula (I), Ka²¹ and Ka²² each independently denote an integer ranging from 0 to 3. When Ka²¹ denotes 2 or 3, plural Ma²¹ and plural Ma²² present may be respectively identical or different from each other; and when Ka²² denotes 2 or 3, plural Ma²⁵ and plural Ma²⁶ present may be respectively identical or different from each other. Both Ka²¹ and Ka²² preferably denote 2.

The anionic moiety in general formula (I) is preferably denoted by general formula (IV) below.

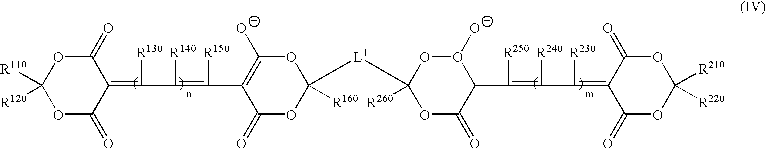

In general formula (IV), R¹¹⁰, R²¹⁰, R¹²⁰, and R²²⁰ each independently denote a hydrogen atom, substituted or unsubstituted alkyl group, or substituted or unsubstituted aryl group. Each of R¹¹⁰, R²¹⁰, R¹²⁰, and R²²⁰ preferably independently denotes an unsubstituted alkyl group. It is preferable for R¹¹⁰ and R²¹⁰ to be identical, for R¹²⁰ and R²²⁰ to be identical, and for the first two to be a different group from the latter two. It is further preferable for R¹¹⁰ and R²¹⁰, and for R¹²⁰ and R²²⁰, to be identical, and for the first two and the latter two to denote different unsubstituted alkyl groups having 1 to 6 carbon atoms.

R¹¹⁰ may be bound to R²¹⁰ and R¹²⁰ may be bound to R²²⁰ to form ring structures. The ring structures that are formed are preferably five to seven-membered rings, more preferably five or six-membered aliphatic rings, with cyclohexane rings being of even greater preference.

R¹³⁰, R¹⁴⁰, R¹⁵⁰, R²³⁰, R²⁴⁰, and R²⁵⁰ each independently denote a hydrogen atom or substituent. Hydrogen atoms, substituted or unsubstituted alkyl groups, substituted or unsubstituted aryl groups, and substituted or unsubstituted heterocyclic groups are preferable. Hydrogen atoms, ethyl groups, methyl groups, and phenyl groups are more preferable. R¹³⁰ and R²³⁰, R¹⁴⁰ and R²⁴⁰, and R¹⁵⁰ and R²⁵⁰ are preferably identical, it being further preferable for all of R¹³⁰, R¹⁴⁰, R¹⁵⁰, R²³⁰, R²⁴⁰, and R²⁵⁰ to denote hydrogen atoms.

R¹⁶⁰ and R²⁶⁰ each independently denote a hydrogen atom, substituted or unsubstituted alkyl group, or substituted or unsubstituted aryl group. Preferable alkyl groups denoted by R¹⁶⁰ and R²⁶⁰ are alkyl groups having 1 to 6 carbon atoms; when the alkyl groups are substituted, examples of preferable substituents are alkoxy groups, amide groups, acyl groups, and ester groups. Preferable aryl groups denoted by R¹⁶⁰ and R²⁶⁰ are aryl groups having 6 to 20 carbon atoms; when the aryl groups are substituted, examples of preferable substituents are alkyl groups, alkoxy groups, amide groups, acyl groups, and ester groups.

R¹⁶⁰ and R²⁶⁰ are preferably identical. When identical, it is preferable for R¹⁶⁰ and R²⁶⁰ to bond together to form a divalent linking group. Preferable divalent linking groups formed by the bonding of R¹⁶⁰ and R²⁶⁰ are alkylene groups having 1 to 6 carbon atoms, with alkylene groups having 1 to 3 carbon atoms being preferred.

L¹ denotes a divalent linking group. Preferably, L¹ denotes a substituted or unsubstituted alkylene group. The alkylene group preferably has 1 to 3 carbon atoms. When a substituent is present on this alkylene group, examples of preferable substituents are alkyl groups having 1 to 6 carbon atoms, alkoxy groups, acyl groups, amide groups, ester groups, and aryl groups.

L¹ is preferably a ring structure formed by R¹⁶⁰ and R²⁶⁰. In this case, preferable ring structures are five and six-membered rings, more preferably aliphatic rings, and further preferably, cyclohexane rings.

n and m each independently denote an integer ranging from 0 to 2, it being preferable for both n and m to denote 2. When n and m denote 2, plural R¹³⁰s, R¹⁴⁰s, R²³⁰s, and R²⁴⁰s that are present may be respectively identical or different from each other.

Specific examples of the above anionic moiety are given below, but the present invention is not limited to these specific examples.

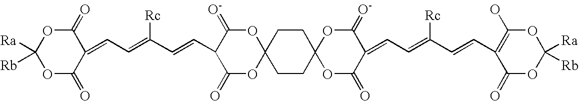

| Compound No. | Ra | Rb | Rc |
|---|---|---|---|
| C-1 | CH₃ | C₂H₅ | H |
| C-2 | CH₃ | C₄H₉-t | H |
| C-3 | C₂H₅ | C₃H₇-i | H |
| C-4 | C₂H₅ | C₂H₅ | H |
| C-5 | CH₃ | C₃H₇-n | H |
| C-6 | CH₃ | C₃H₇-n | CH₃ |
| C-7 | CH₃ | CH₂OCH₃ | H |
| C-8 | CH₃ | C₂H₄CO₂CH₃ | H |
| C-9 | CH₃ | C₂H₄CO₂C₂H₅ | H |
| C-10 | CH₃ | CH₃ | H |

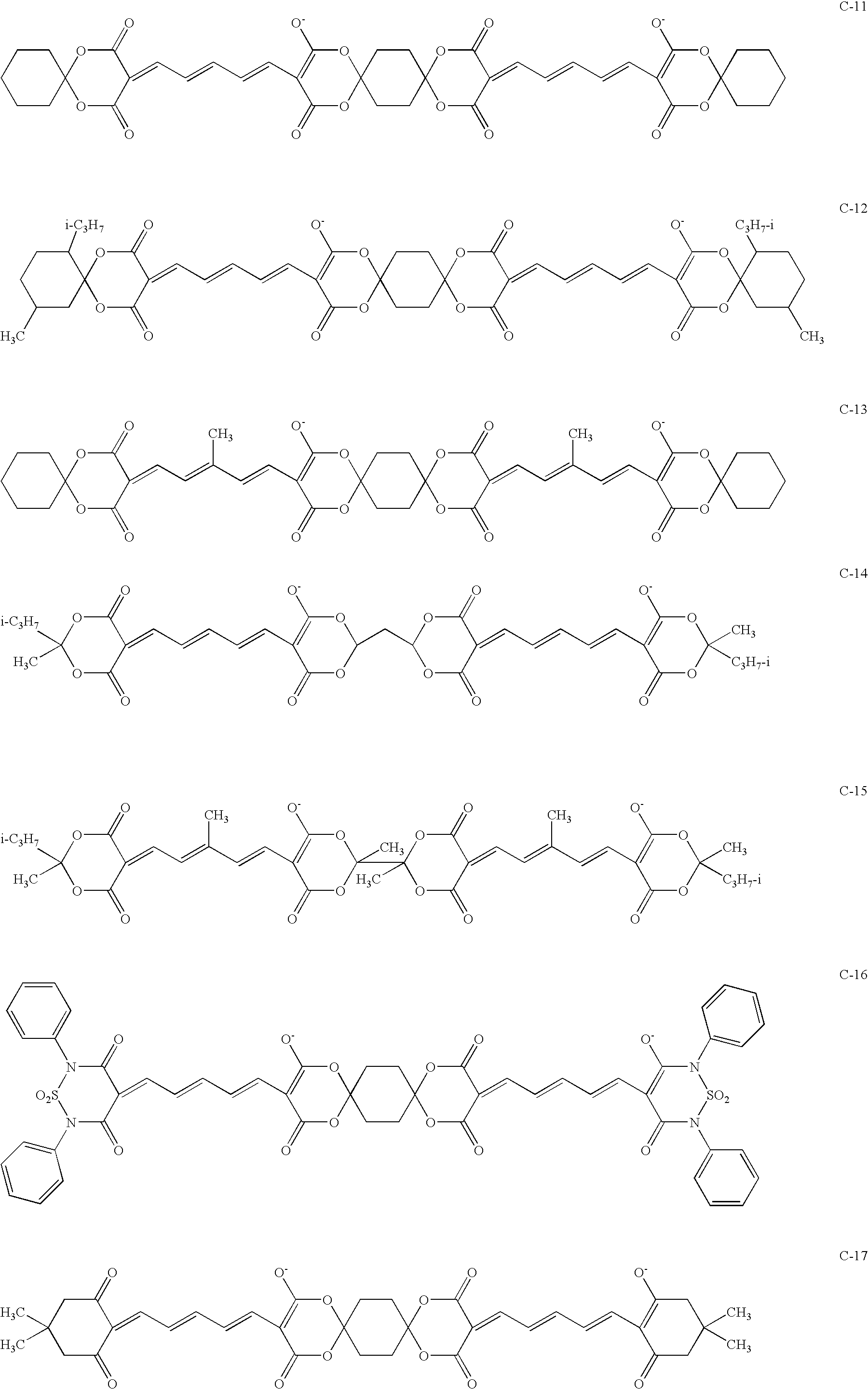

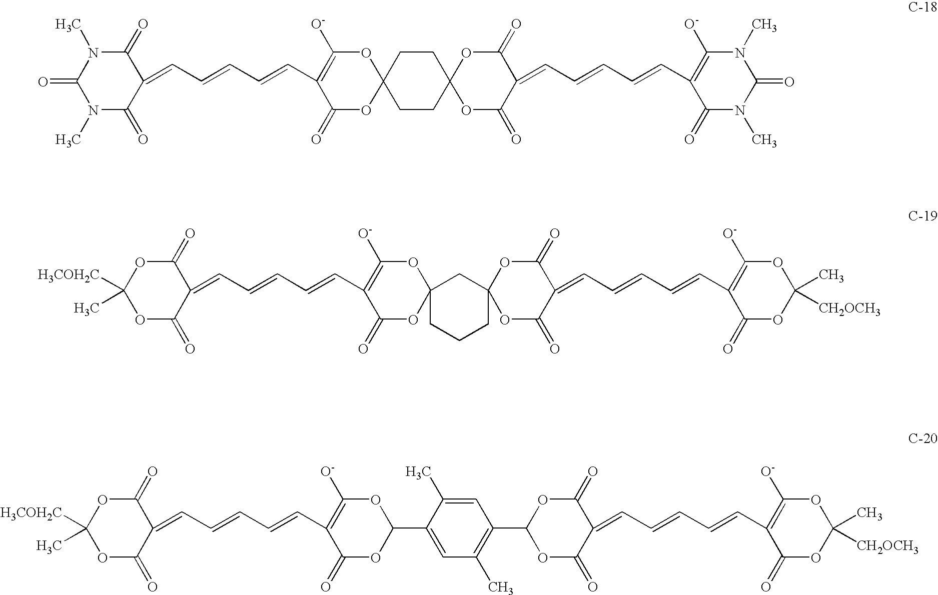

The cationic moiety in general formula (I) will be described below.

In general formula (I), Q denotes a cation of valence n, and n denotes an integer ranging from 1 to 6, preferably an integer ranging from 2 to 4. The ion denoted by Q is not specifically limited, and may be an ion comprised of an inorganic compound or an ion comprised of an organic compound. Examples of the monovalent cation denoted by Q are: sodium ions, potassium ions, and other metal ions; and quaternary ammonium ions; oxonium ions; sulfonium ions; phosphonium ions; selenonium ions, iodonium ions, and other onium ions.

The cation denoted by Q is preferably an onium ion, more preferably a quaternary ammonium ion. The 4,4′-bipyridinium cation denoted by general formula (I-4) in Japanese Unexamined Patent Publication (KOKAI) No. 2000-52658, which is expressly incorporated herein by reference in its entirety, and the 4,4′-bipyridinium cation disclosed in Japanese Unexamined Patent Publication (KOKAI) No. 2002-59652, which is expressly incorporated herein by reference in its entirety, are preferred among quaternary ammonium ions.

Examples of cations that are preferable from the perspective of recording characteristics in optical disk uses are the quadrivalent caion denoted by general formula (II) and the divalent cation denoted by general formula (III). General formulas (II) and (III) will be successively described below.

### General Formula (II)

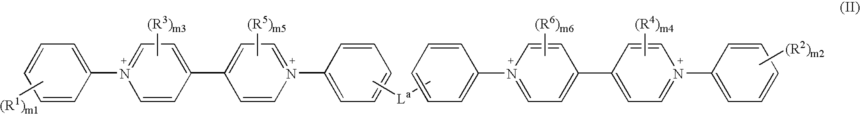

In general formula (II), R¹, R², R³, R⁴, R⁵, and R⁶ each independently denote a substituent.

Examples of the substituents denoted by R³ and R⁴ are alkyl groups (preferably having 1 to 30 carbon atoms, more preferably having 1 to 20 carbon atoms, and further preferably having 1 to 10 carbon atoms, such as methyl groups, ethyl groups, isopropyl groups, tert-butyl groups, n-octyl groups, n-decyl groups, n-hexadecyl groups, cyclopropyl groups, cyclopentyl groups, and cyclohexyl groups); alkenyl groups (preferably having 2 to 30 carbon atoms, more preferably having 2 to 20 carbon atoms, and further preferably having 2 to 10 carbon atoms, such as vinyl groups, allyl groups, 2-butenyl groups, and 3-pentenyl groups); alkynyl groups (preferably having 2 to 30 carbon atoms, more preferably having 2 to 20 carbon atoms, and further preferably having 2 to 10 carbon atoms, such as propargyl groups and 3-pentynyl groups), aryl groups (preferably having 6 to 30 carbon atoms, more preferably 6 to 20 carbon atoms, and further preferably having 6 to 12 carbon atoms, such as phenyl groups, p-methylphenyl groups, naphthyl groups, and anthranyl groups), amino groups (preferably having 0 to 30 carbon atoms, more preferably having 0 to 20 carbon atoms, and further preferably having 0 to 10 carbon atoms, such as amino groups, methylamino groups, dimethylamino groups, diethylamino groups, dibenzylamino groups, diphenylamino groups, and ditolylamino groups), alkoxy groups (preferably having 1 to 30 carbon atoms, more preferably having 1 to 20 carbon atoms, and further preferably having 1 to 10 carbon atoms, such as methoxy groups, ethoxy groups, butoxy groups, and 2-ethylhexyloxy groups), aryloxy groups (preferably having 6 to 30 carbon atoms, more preferably having 6 to 20 carbon atoms, and further preferably having 6 to 12 carbon atoms, such as phenyloxy groups, 1-naphthyloxy groups, and 2-naphthyloxy groups), aromatic heterocyclic oxy groups (preferably having 1 to 30 carbon atoms, more preferably having 1 to 20 carbon atoms, and further preferably having 1 to 12 carbon atoms, such as pyridyloxy groups, pyrazyloxy groups, pyrimidyloxy groups, and quinolyloxy groups), acyl groups (preferably having 1 to 30 carbon atoms, more preferably having 1 to 20 carbon atoms, and further preferably having 1 to 12 carbon atoms, such as acetyl groups, benzoyl groups, formyl groups, and pivaloyl groups), alkoxycarbonyl groups (preferably having 2 to 30 carbon atoms, more preferably having 2 to 20 carbon atoms, and further preferably having 2 to 12 carbon atoms, such as methoxycarbonyl groups and ethoxycarbonyl groups), aryloxycarbonyl groups (preferably having 7 to 30 carbon atoms, more preferably having 7 to 20 carbon atoms, and further preferably having 7 to 12 carbon atoms, such as phenyloxycarbonyl groups), acyloxy groups (preferably having 2 to 30 carbon atoms, more preferably having 2 to 20 carbon atoms, and further preferably having 2 to 10 carbon atoms, such as acetoxy groups and benzoyloxy groups), acylamino groups (preferably having 2 to 30 carbon atoms, more preferably having 2 to 20 carbon atoms, and further preferably having 2 to 10 carbon atoms, such as acetylamino groups, and benzoylamino groups), alkoxycarbonylamino groups (preferably having 2 to 30 carbon atoms, more preferably having 2 to 20 carbon atoms, and further preferably having 2 to 12 carbon atoms, such as methoxycarbonylamino groups), aryloxycarbonylamino groups (preferably having 7 to 30 carbon atoms, more preferably having 7 to 20 carbon atoms, and further preferably having 7 to 12 carbon atoms, such as phenyloxycarbonylamino groups), sulfonylamino groups (preferably having 1 to 30 carbon atoms, more preferably having 1 to 20 carbon atoms, and further preferably having 1 to 12 carbon atoms, such as methanesulfonylamino groups, and benzenesulfonylamino groups), sulfamoyl groups (preferably having 0 to 30 carbon atoms, more preferably having 0 to 20 carbon atoms, and further preferably having 0 to 12 carbon atoms, such as sulfamoyl groups, methylsulfamoyl groups, dimethylsulfamoyl groups, and phenylsulfamoyl groups), carbamoyl groups (preferably having 1 to 30 carbon atoms, more preferably having 1 to 20 carbon atoms, and further preferably having 1 to 12 carbon atoms, such as carbamoyl groups, methylcarbamoyl groups, diethylcarbamoyl groups, and phenylcarbamoyl groups), alkylthio groups (preferably having 1 to 30 carbon atoms, more preferably having 1 to 20 carbon atoms, and further preferably having 1 to 12 carbon atoms, such as methylthio groups and ethylthio groups), arylthio groups (preferably having 6 to 30 carbon atoms, more preferably having 6 to 20 carbon atoms, and further preferably having 6 to 12 carbon atoms, such as phenylthio groups), aromatic heterocyclic thio groups (preferably having 1 to 30 carbon atoms, more preferably having 1 to 20 carbon atoms, and further preferably having 1 to 12 carbon atoms, such as pyridylthio groups, 2-benzimidazolylthio groups, 2-benzoxazolylthio groups, and 2-benzthiazolyl groups), sulfonyl groups (preferably having 1 to 30 carbon atoms, more preferably having 1 to 20 carbon atoms, and further preferably having 1 to 12 carbon atoms, such as mesyl groups and tosyl groups), sulfinyl groups (preferably having 1 to 30 carbon atoms, more preferably having 1 to 20 carbon atoms, and further preferably having 1 to 12 carbon atoms, such as methanesulfinyl groups and benzenesulfinyl groups), ureido groups (preferably having 1 to 30 carbon atoms, more preferably having 1 to 20 carbon atoms, and further preferably having 1 to 12 carbon atoms, such as ureido groups, methylureido groups, and phenylureido groups), phosphoramide groups (preferably having 1 to 30 carbon atoms, more preferably having 1 to 20 carbon atoms, and further preferably having 1 to 12 carbon atoms, such as diethylphosphoramide groups and phenylphosphoramide groups), hydroxy groups, mercapto groups, halogen atoms (such as fluorine atoms, chlorine atoms, bromine atoms, and iodine atoms), cyano groups, sulfo groups, carboxyl groups, nitro groups, hydroxamic acid groups, sulfino groups, hydrazino groups, imino groups, aromatic heterocyclic groups (preferably having 1 to 30 carbon atoms, more preferably 1 to 12 carbon atoms; examples of the hetero atoms being nitrogen atoms, oxygen atoms, and sulfur atoms; and specific examples of which are imidazolyl groups, pyridyl groups, quinolyl groups, furyl groups, thienyl groups, piperidyl groups, morpholino groups, benzoxazolyl groups, benzimidazolyl groups, benzthiazolyl groups, carbazolyl groups, and azepinyl groups), and silyl groups (preferably having 3 to 40 carbon atoms, more preferably having 3 to 30 carbon atoms, and further preferably having 3 to 24 carbon atoms, such as trimethylsilyl groups and triphenylsilyl groups). These substituents may be further substituted. Alkyl groups, aryl groups, heterocyclic groups, amino groups, alkoxy groups, acyl groups, acyloxy groups, acylamino groups are preferred and alkyl groups, aryl groups, alkoxy groups, and acyl groups are of greater preference. The substituents denoted by R³ and R⁴ may themselves be bound together. That is, adjacent pyridine rings may be linked by the linking group to which R³ and R⁴ are bound. Further, R³ and R⁴ may form a ring with a benzene ring on which they are substituted.

R¹ and R² each independently denote a substituent. Substituents having a nitrogen cation are examples in addition to the above-listed substituents given by way of example in the description of the substituents of R³ and R⁴ above. In this context, the term “nitrogen cation” means a cation that comprises one or more nitrogen atoms at least one of which has a positive charge.

By way of example, the nitrogen cation is preferably a tetra-substituted nitrogen atom cation (examples of the substituents being the alkyl groups, aryl groups, and aromatic heterocyclic groups given by way of example for the substituents of R³ and R⁴) or a nitrogen-containing aromatic heterocyclic cation.

The tetra-substituted nitrogen atom cation is preferably the following cation:

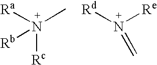

In the above, R^{a}, R^{b}, R^{c}, R^{d}, and R^{e} each independently denote one of the alkyl groups, aryl groups, or aromatic heterocyclic groups given by way of example for the substituents of R³ and R⁴.

Examples of nitrogen-containing aromatic heterocyclic cations are pyridinium cations, imidazolium cations, thiazolium cations, oxazolium cations, and iminium cations, and specific examples are the following cations:

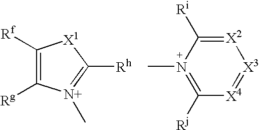

In the above, X¹ denotes O, N, S, or CR (where R denotes a hydrogen atom or substituent), preferably N. R^{f}, R^{g}, and R^{h} each independently denote a hydrogen atom or substituent. R^{g} and R^{h} may each form rings with the N contained in heterocycles. When X¹ denotes CR, X¹ and R^{f} or R^{h} may be linked to form a ring. X², X³, and X⁴ each independently denote N or CR′ (where R′ denotes a hydrogen atom or a substituent). Rⁱ and R^{j} each independently denotes a hydrogen atom or a substituent. Rⁱ and Rⁱ may each form a ring with the N contained in heterocycles. When X² denotes CR′, X² and Rⁱ may be linked to form a ring, and when X⁴ denotes CR′, X⁴ and R^{j} may be linked to form a ring. Examples of the above substituent are the alkyl groups, aryl groups, and aromatic heterocyclic groups given by way of example of substituents of R³ and R⁴ above.

A specific example of the above nitrogen-containing aromatic heterocyclic cation is a compound in the form of the nitrogen-containing aromatic heterocycle below in which at least one nitrogen has been substituted.

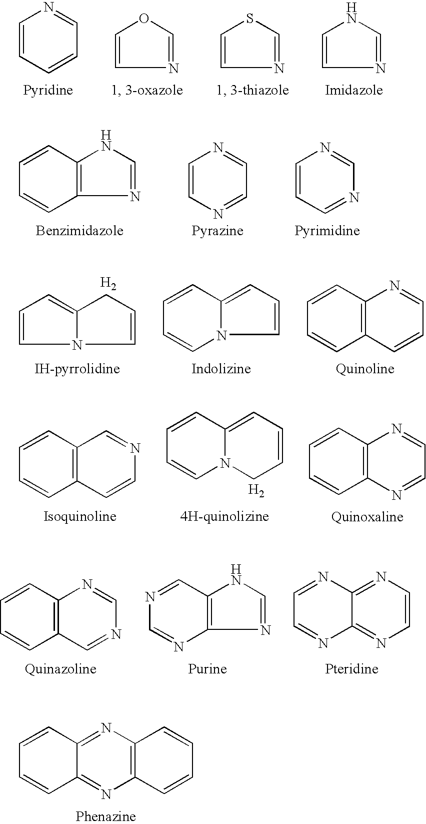

Among the above specific examples, preferable examples are pyridine, 1,3-oxazol, 1,3-thiazol, imidazol, and benzimidazol in which at least one nitrogen atom has been substituted.

The details, such as preferable examples of the substituents denoted by R⁵ and R⁶, are as given in the description of the substituents of R³ and R⁴ above. In general formula (II), particularly preferable examples of the substituents denoted by R¹, R², R³, R⁴, R⁵, and R⁶ are alkyl groups, aryl groups, alkoxy groups, aryloxy groups, acyl groups, alkoxycarbonyl groups, amide groups, sulfamoyl groups, and ureido groups.

In general formula (II), m1 and m2 each independently denote an integer ranging from 0 to 5, preferably an integer ranging from 0 to 2. When m1 denotes an integer ranging from 2 to 5, plural R¹ present may be identical or different from each other. When m2 denotes an integer ranging from 2 to 5, plural R² present may be identical or different from each other.

m3 and m4 each independently denote an integer ranging from 0 to 4, preferably an integer ranging from 0 to 2, and more preferably 0. When m3 denotes an integer ranging from 2 to 4, plural R³ present may be identical or different from each other. When m4 denotes an integer ranging from 2 to 4, plural R⁴ present may be identical or different from each other.

m5 and m6 each independently denote an integer ranging from 0 to 4, preferably an integer ranging from 0 to 2, and more preferably, 0. When m5 denotes an integer ranging from 2 to 4, plural R⁴ present may be identical or different from each other. When m6 denotes an integer ranging from 2 to 4, plural R⁶ present may be identical or different from each other.

In general formula (II), L^{a} denotes a divalent linking group, preferably a single bond, oxygen atom (viz., ether liking group), sulfur atom (viz., thioether liking group), nitrogen atom (viz., imino liking group), methylene group, phenylene group, carbonyl group, sulfanyl group, amide group, or group comprised of a combination thereof. The following linking groups are particularly preferable.

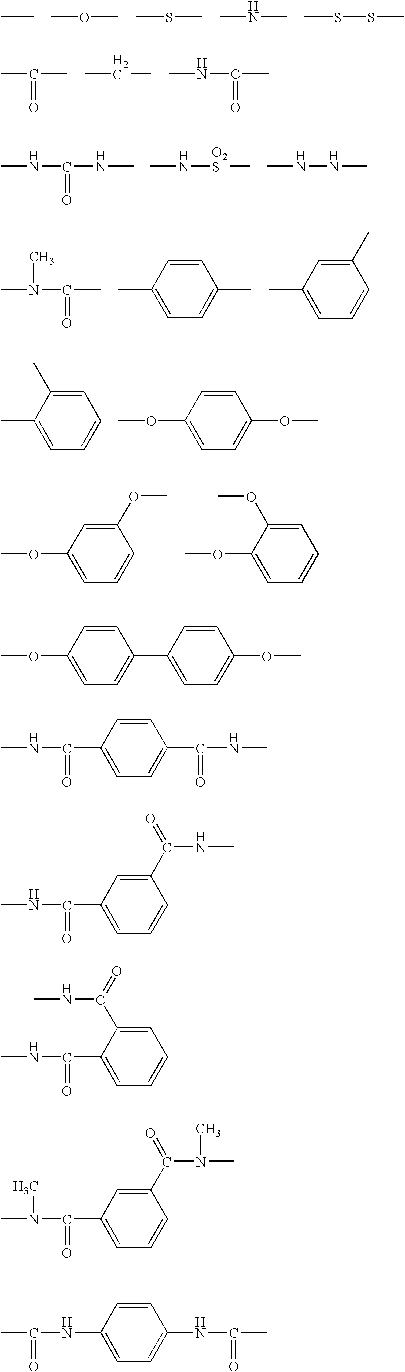

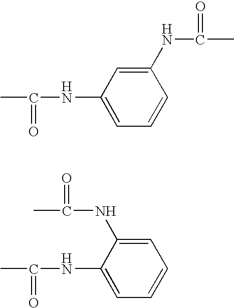

Specific examples of the cationic moiety denoted by general formula (II) are given below. However, the present invention is not limited to these specific examples.

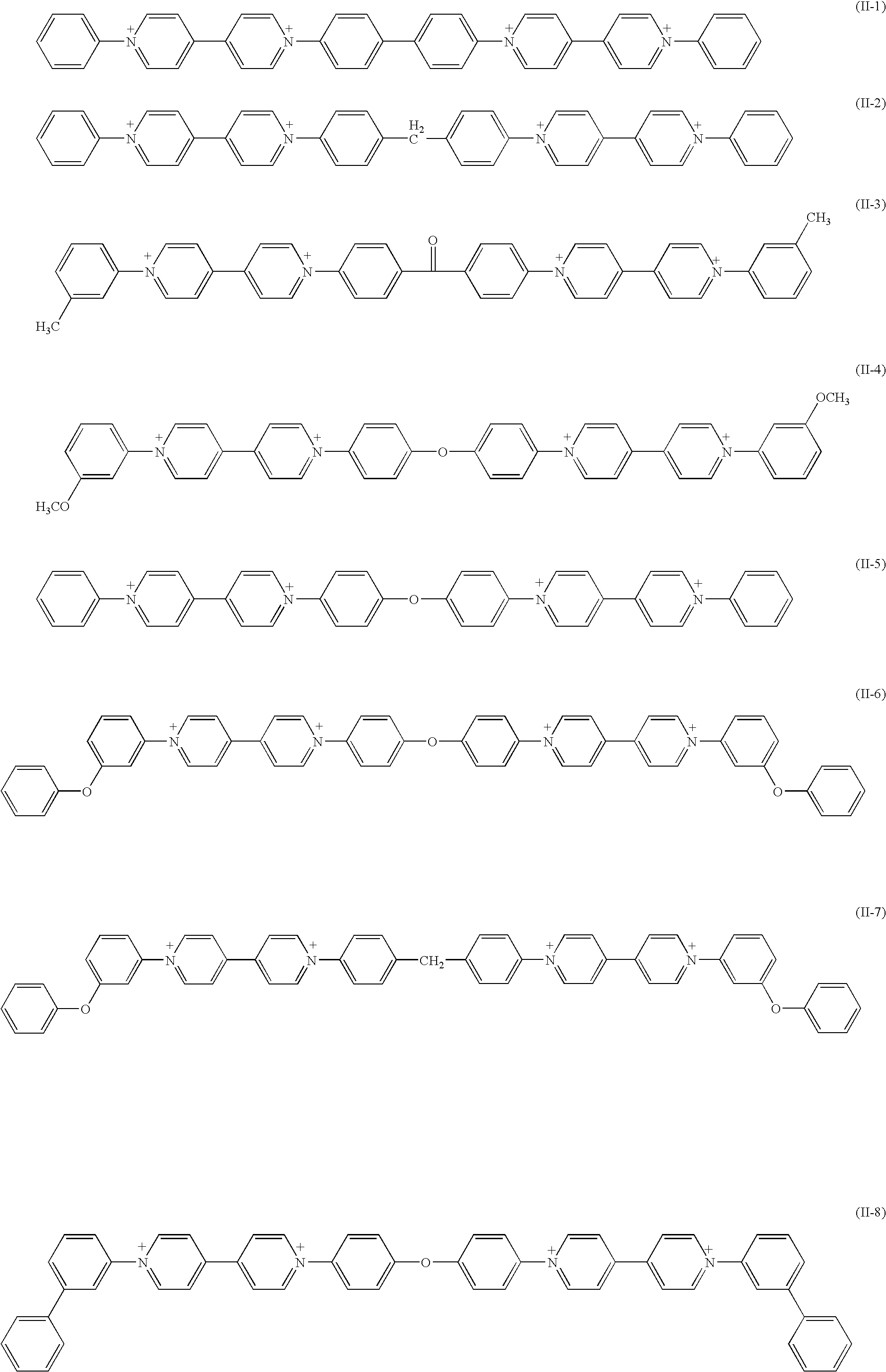

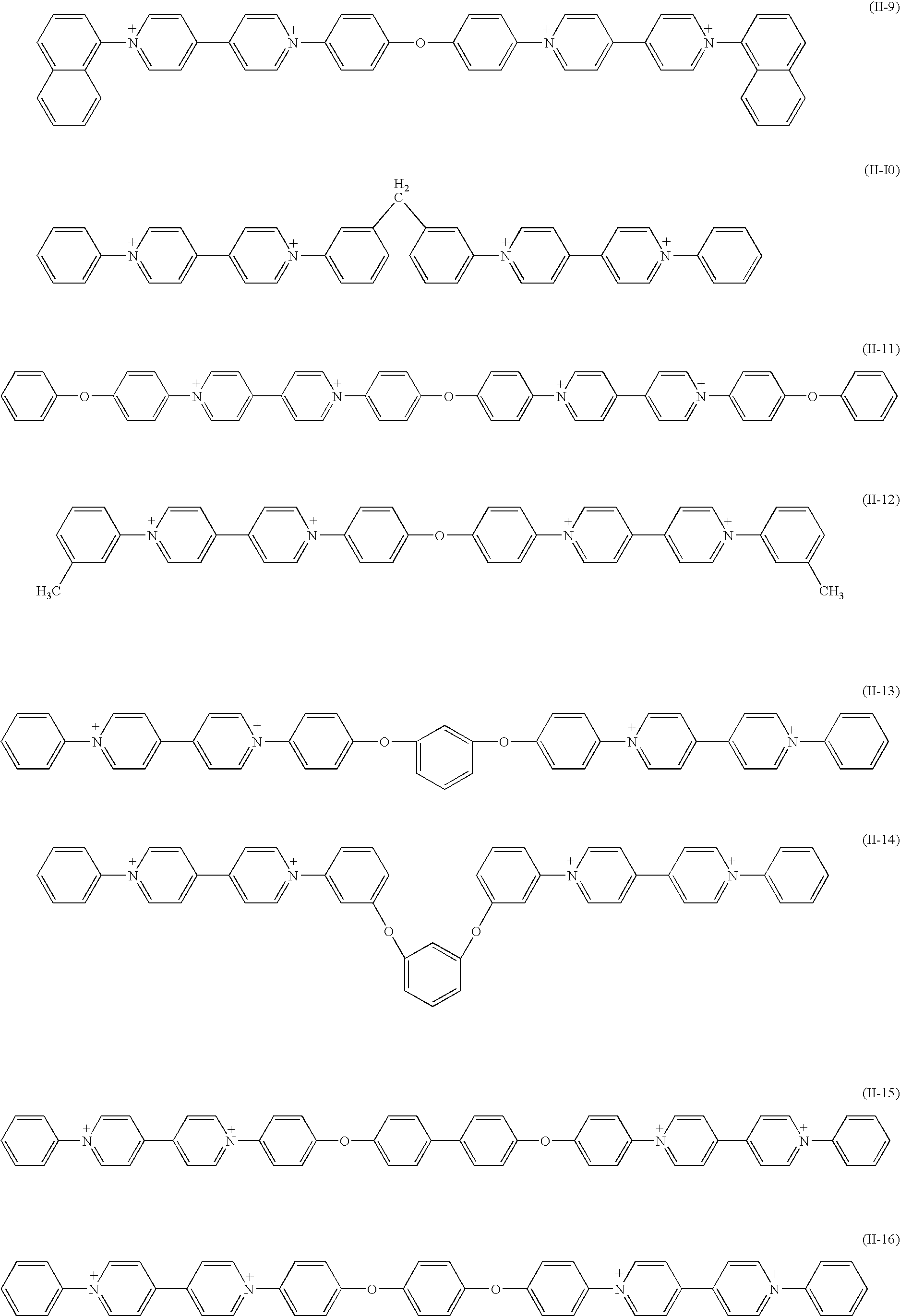

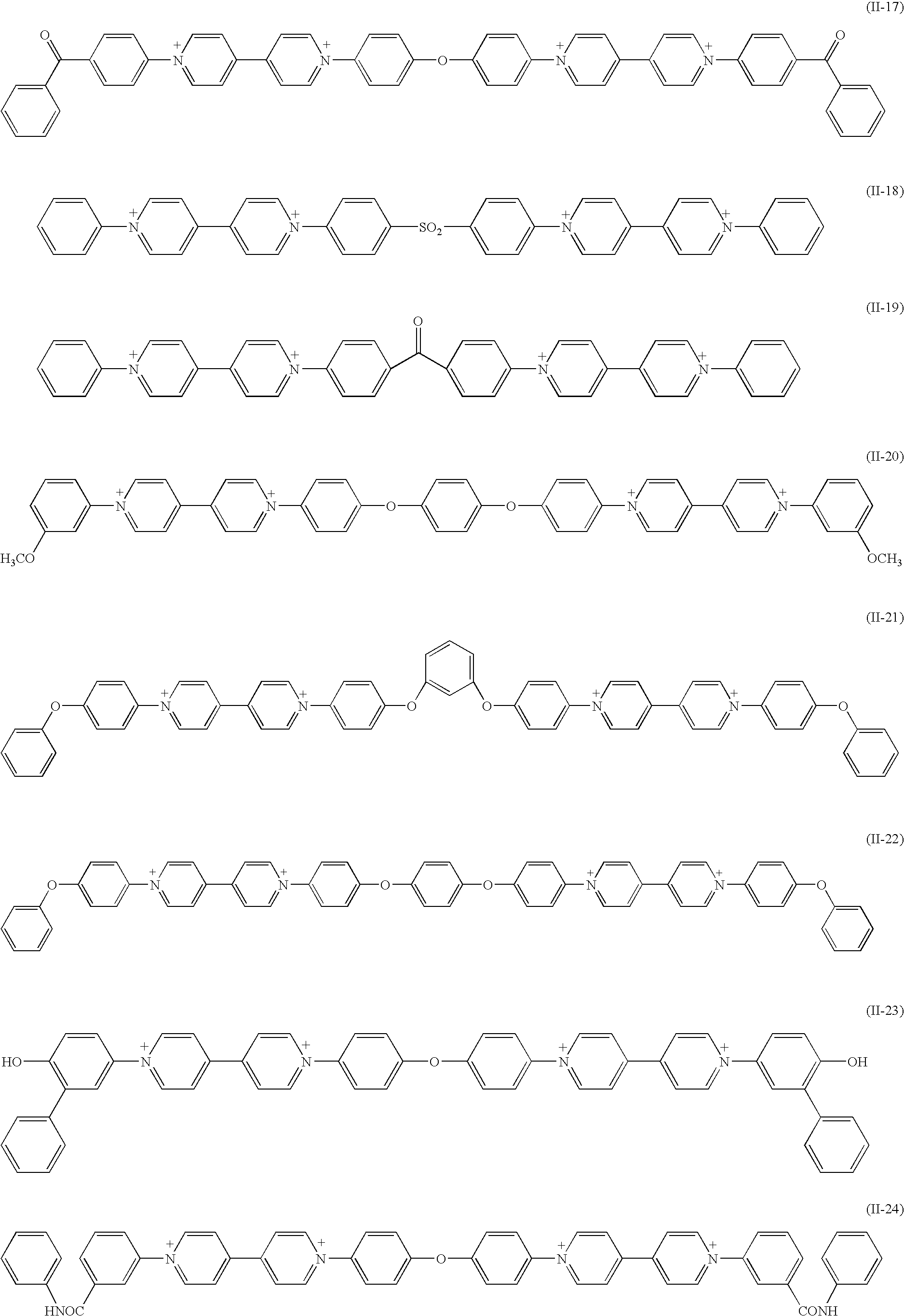

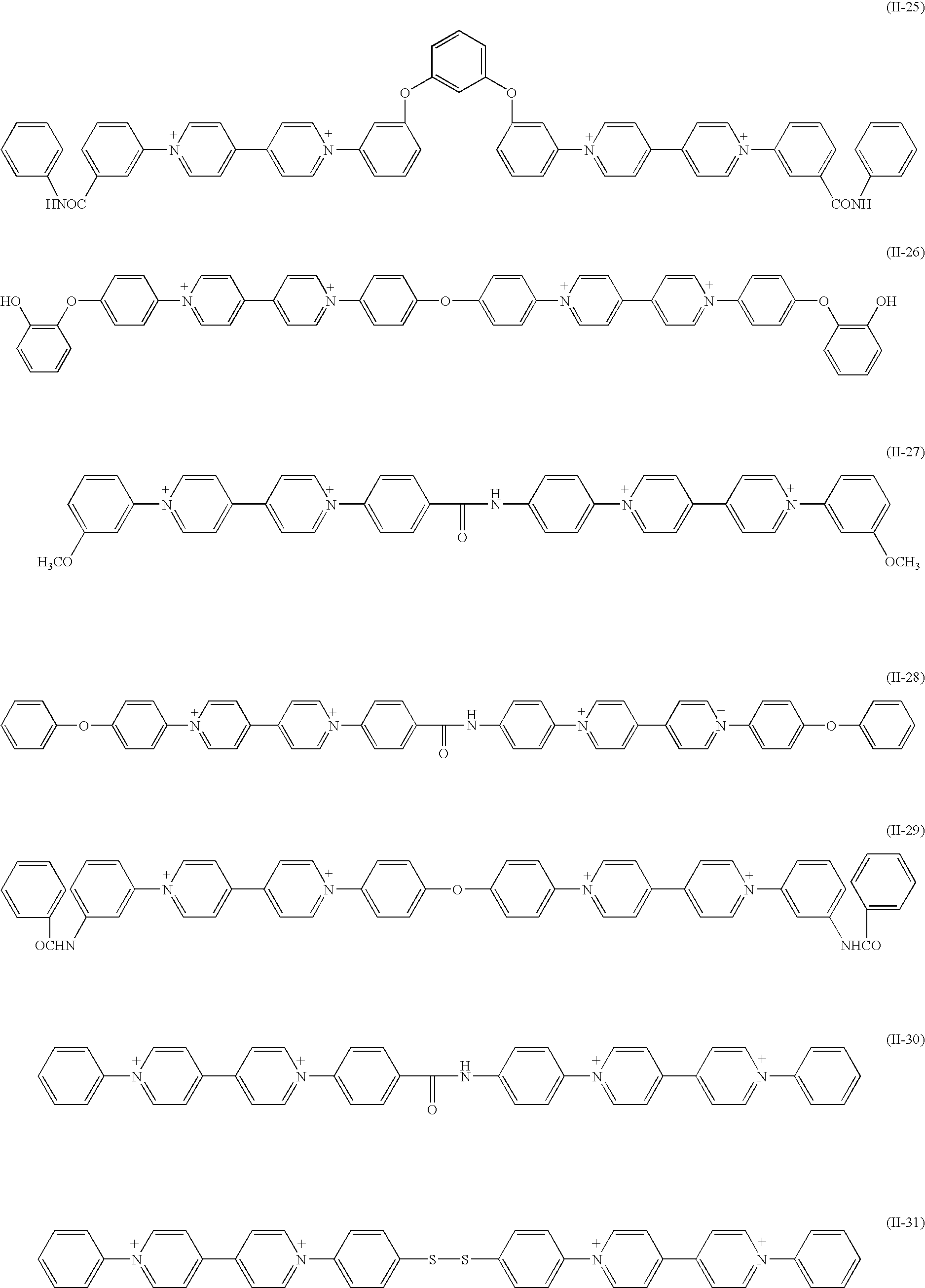

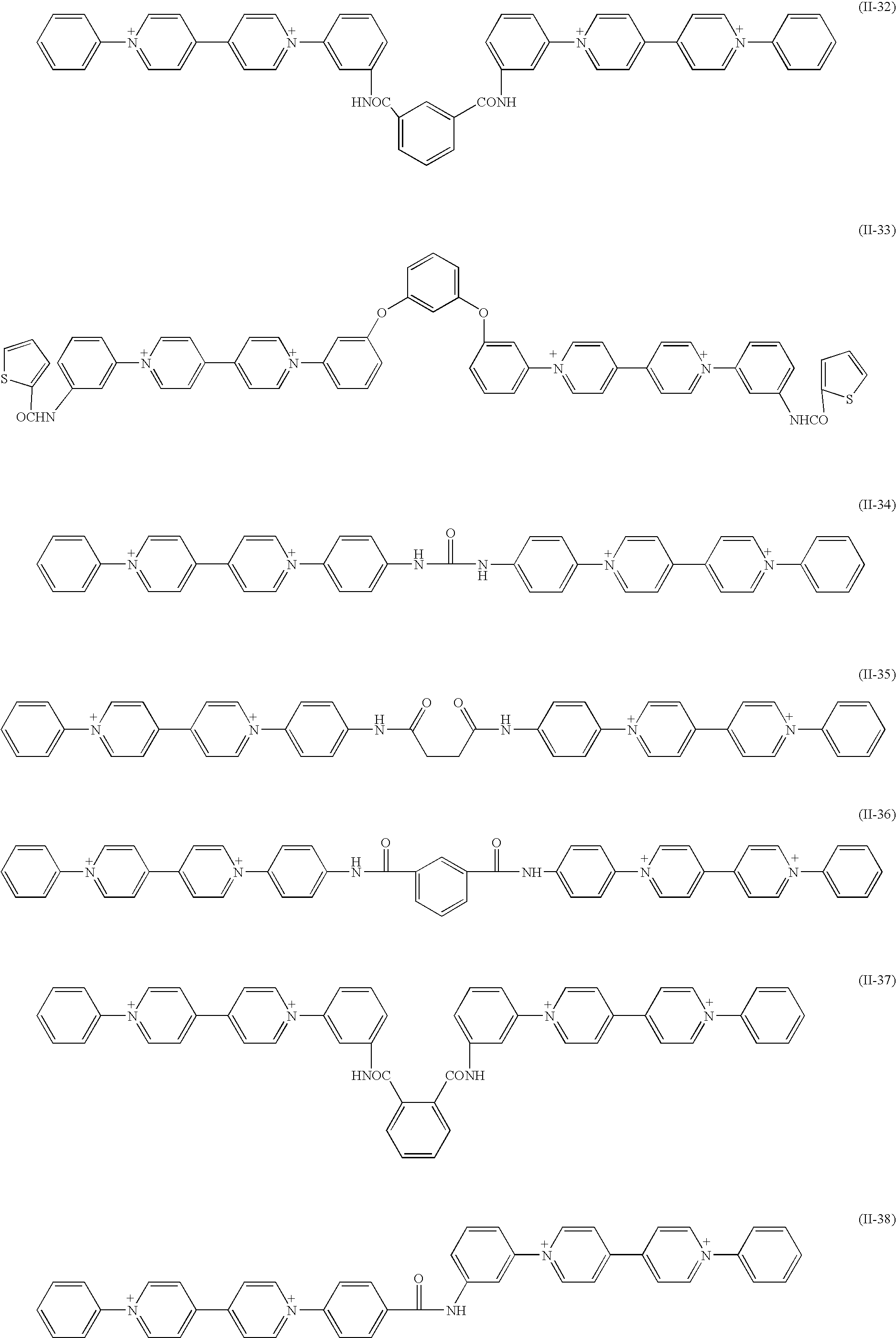

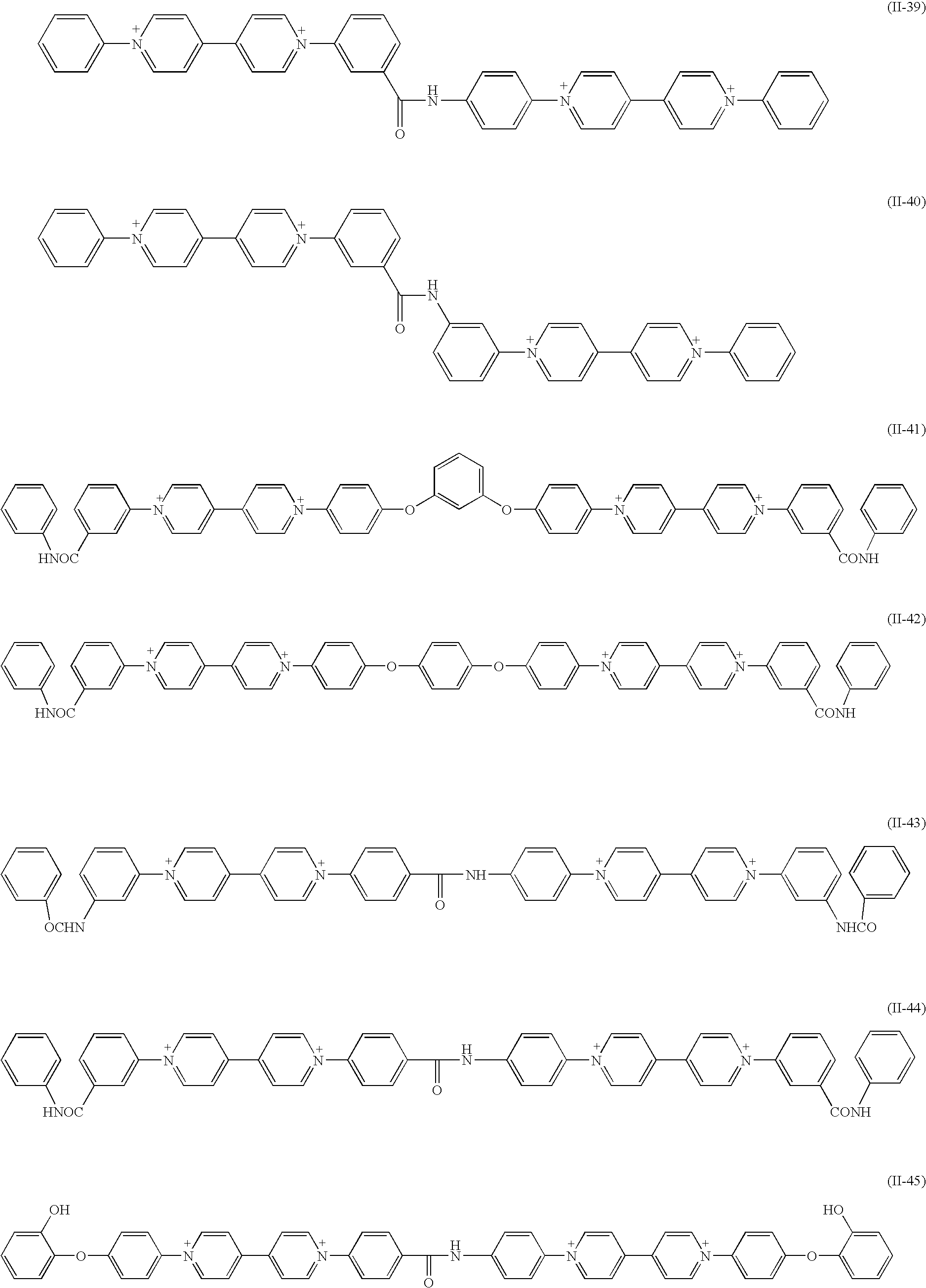

### General Formula (III)

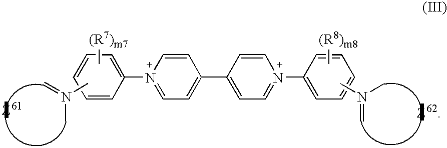

In general formula (III), Z⁶¹ and Z⁶² each independently denote an atom group forming a nitrogen-containing heteroaryl ring, preferably forming a nitrogen-containing hetero five-membered group; more preferably a pyrrole ring, imidazole ring, pyrazole ring, or a benzo-condensed ring or hetero-condensed ring thereof.

R⁷ and R⁸ each independently denote a substituent, the details of which are as set forth for R³ and R⁴ in general formula (II) above.

In general formula (III), m7 and m8 each independently denote an integer ranging from 0 to 4, with 0 or 1 being preferable. When m7 denotes an integer ranging from 2 to 4, plural R⁷ present may be identical or different from each other, and when m8 denotes in integer ranging from 2 to 4, plural R⁸ present may be identical or different from each other.

Specific examples of the cationic moiety denoted by general formula (III) are given below. However, the present invention is not limited to these specific examples.

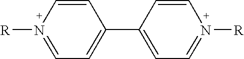

| | —R |
|---|---|
| (III-1) | 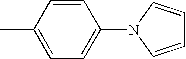 |
| (III-2) | 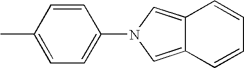 |
| (III = 3) | 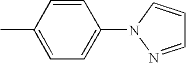 |
| (III-4) | 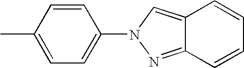 |
| (III-5) | 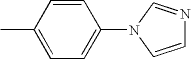 |
| (III-6) | 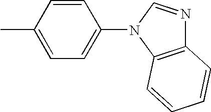 |
| (III-7) | 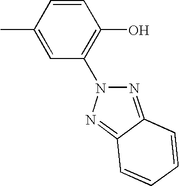 |

The cationic moiety denoted by general formula (II) can be synthesized by substituting with aniline or a heteroarylamine a pyridinium compound in which dinitrobenzene or a heteroaryl has been substituted onto the nitrogen, as described in Japanese Unexamined Patent Publication (KOKAI) No. 2003-128654, which is expressly incorporated herein by reference in its entirety. Further, the cation compound denoted by general formula (II) comprising three or more cation groups can be synthesized using a compound already comprising a cation group in the form of the aniline or heteroarylamine, or synthesized by treating the substituent of an aryl group or heteroaryl group on the nitrogen of a bipyridinium compound with an onium.

The cationic moiety denoted by general formula (III) can be synthesized by the method described in Bull. Chem. Soc. Jpn., Vol. 64, p. 321 (1991), which is expressly incorporated herein by reference in its entirety, by the method described in Japanese Unexamined Patent Publication (KOKAI) No. 2003-128654, which is expressly incorporated herein by reference in its entirety, or the like.

A method of synthesizing bis-type oxonol compounds is disclosed in European Patent EP1 424 691 A2, which is expressly incorporated herein by reference in its entirety.

Specific examples of the compound denoted by general formula (I) having a film-softening temperature of equal to or higher than 290° C. are given below. However, the present invention is not limited to the specific examples given below.

| | Anionic | Cationic |
|---|---|---|
| Dye | moiety | moiety |
| D-1 | C-5 | II-1 |
| D-2 | C-5 | II-2 |
| D-3 | C-5 | II-3 |
| D-4 | C-5 | II-4 |
| D-5 | C-5 | II-5 |
| D-6 | C-9 | II-6 |
| D-7 | C-4 | II-7 |
| D-8 | C-9 | II-8 |
| D-9 | C-9 | II-9 |
| D-10 | C-11 | II-10 |
| D-11 | C-9 | II-11 |
| D-12 | C-9 | II-12 |
| D-13 | C-9 | II-13 |
| D-14 | C-5 | II-14 |
| D-15 | C-5 | II-15 |
| D-16 | C-9 | II-16 |
| D-17 | C-5 | II-17 |
| D-18 | C-9 | II-18 |
| D-19 | C-9 | II-19 |
| D-20 | C-11 | II-20 |
| D-21 | C-9 | II-21 |
| D-22 | C-5 | II-22 |
| D-23 | C-9 | II-23 |
| D-24 | C-5 | II-24 |
| D-25 | C-5 | II-25 |
| D-26 | C-5 | II-26 |
| D-27 | C-9 | II-27 |
| D-28 | C-5 | II-28 |
| D-29 | C-5 | II-29 |
| D-30 | C-5 | II-30 |
| D-31 | C-5 | II-31 |
| D-32 | C-4 | II-32 |
| D-33 | C-5 | II-33 |
| D-34 | C-9 | II-34 |
| D-35 | C-5 | II-35 |
| D-36 | C-9 | II-36 |
| D-37 | C-5 | II-37 |
| D-38 | C-9 | II-38 |
| D-39 | C-5 | II-39 |
| D-40 | C-5 | II-40 |
| D-41 | C-5 | II-41 |
| D-42 | C-5 | II-42 |
| D-43 | C-5 | II-43 |
| D-44 | C-9 | II-44 |
| D-45 | C-5 | III-1 |
| D-46 | C-5 | III-2 |
| D-47 | C-5 | III-3 |
| D-48 | C-5 | III-4 |
| D-49 | C-5 | III-5 |
| D-50 | C-5 | III-6 |
| D-51 | C-9 | III-1 |
| D-52 | C-9 | III-2 |
| D-53 | C-9 | III-3 |
| D-54 | C-9 | III-4 |
| D-55 | C-9 | III-5 |
| D-56 | C-9 | III-6 |
| D-57 | C-5 | III-7 |

The optical information recording medium of the present invention comprises a recording layer comprising the above-described dye. Information can be recorded in the recording layer by irradiation of a laser beam. Incorporating a dye having a film-softening temperature of equal to or higher than 290° C. in the recording layer permits a reduction in thermal interference during high-speed recording. This then can suppress increased jitter and enhance recording characteristics. The optical recording medium of the present invention in which thermal interference during high-speed recording is reduced in this manner preferably satisfies Equation (1) below when an EFM signal is recorded in a random pattern at a linear recording velocity of 41.88 m/s:

Average 3T space length/average 14T space length>0.211 (1)

During high-speed recording, the temperature rises in recording pit portions due to the pits being recorded at high recording power. The rise in the temperature of recording mark portions causes the dye around the recording pits to undergo thermal degradation, and the pits tend to widen (thermal interference). The tendency is for the distance between pits to shorten; this is pronounced in the minimum space (for example, 3T space in a DVD). That is, the shorter the space is, the broader the preceding and following pits tend to become due to the above-described effect of thermal interference, resulting in shortening the length of the space. When this effect is significant, the mark length varies based on the length of the space of the preceding and following pits, and jitter ends up increasing during recording. Accordingly, calculating the ratio of the minimum space in the form of the 3T space to the 14T space permits evaluation of the above effect of thermal interference on recording pits. In the optical information recording medium of the present invention, the incorporation of the above-described dye into the recording layer can yield a ratio of the average 3T space length to the average 14T space length (average 3T space length/average 14T space length) during the recording of an EFM signal in a random pattern at a linear recording velocity of 41.88 m/s of greater than 0.211. Suppressing thermal interference during high-speed recording in this manner can yield a broad power margin. However, when the 3T space becomes excessively long, the jitter of the recording signal tends to deteriorate. Thus, the average 3T space length divided by the average 14T space length is preferably less than 0.225. That is, Equation (1) is preferably Equation (1)′ below. Equation (1) is more preferably Equation (1)″ below.

0.211<average 3T space length/average 14T space length<0.225 (1)′

0.214<average 3T space length/average 14T space length<0.220 (1)″

The above-described ratio of the average 3T space length to the average 14T space length is a value that can be calculated by the following method, for example.

Using a DDU-1000 and a multisignal generator (made by Pulstec Industrial Co., Ltd., laser wavelength 655.9 nm, object lens numerical aperture 0.65), the linear speed is set to 41.88 m/s, and an 8-16 modulated signal is recorded. After recording, the average 3T space length and the average 14T space length are measured by the following method. Using a DDU-1000 (made by Pulstec Industrial Co., Ltd., laser wavelength 655.9 nm, object lens numerical aperture 0.65), the linear speed is set to 3.49 m/s and the 8-16 signal that has been recorded is reproduced. A time interval analyzer TA320 (made by Yokogawa Electric Corp.) is used on the reproduced signal, with the mode set to “HARDWARE HIST” and the function set to “PULSE WITH”. The RF signal of the DDU-1000 is inputted to CHA, and a histogram of the 3T to 14T space is measured. Further, markers are used to measure the average length of the 3T and 14T spaces. The 12× recording-use strategy described in DVD+R 4.7 GB Basic Format Specifications Version 3.0 is employed, with the various parameters set as set forth in Table 1, described further below. Recording is conducted with 10 stages of variation centered on the optimal recording power.

In the optical information recording medium of the present invention, a dye with a film-softening temperature of equal to or higher than 290° C. is incorporated into the recording layer. A dye having a film-softening temperature of equal to or higher than 290° C., or combinations of two or more such dyes, may be employed in the recording layer. The dye that is comprised in the recording layer may be comprised of just the dye having a film-softening temperature of equal to or higher than 290° C., or may be a combination of the above-described dye and other dyes. Examples of other dyes that may be employed in combination are dyes having a maximum absorption wavelength in an amorphous film of equal to or higher than 600 nm but less than 720 nm. The maximum absorption wavelength in an amorphous film of the above dye having a film-softening temperature of equal to or higher than 290° C. is preferably equal to or higher than 500 nm but less than 600 nm. When employing the other dye in combination with the above-described dye as a recording material, from the perspectives of enhancing recording characteristics and manufacturing suitability, the proportion of the above-described dye having a film-softening temperature of equal to or higher than 290° C. in the recording material is preferably 80 to 99 weight percent and the proportion of the other dye is preferably 1 to 20 weight percent.

The optical information recording medium of the present invention is not specifically limited other than that it comprises the above-described dye in the recording layer. It is preferably a recordable DVD (digital versatile disk). Recordable DVDs include those having a single recording layer and those having a double recording layer. There are also DVD-Rs and DVD+Rs. The optical information recording medium of the present invention may be in any of these forms.

The information recording medium of (1) below is an example of a preferable embodiment of a DVD-R optical information recording medium having a single recording layer, and that of (2) below is an example of a DVD-R optical information recording medium having a double recording layer:

(1) An optical information recording medium comprising:

a layered member comprised of a recording layer containing the above-described dye and a reflective layer provided on a transparent round support having a thickness of 0.6±0.1 mm on which are formed pre-grooves at a track pitch of 0.6 to 0.9 micrometer, and a transparent round protective support of the same shape as the round support of the layered member,

the layered member and the protective support being bonded together with the recording layer on the inside to constitute a total thickness of 1.2±0.2 mm.

(2) An optical information recording medium comprising two layered members, each of which is comprised of a recording layer containing the above-described dye and a reflective layer provided on a transparent round support having a thickness of 0.6±0.1 mm on which are formed pre-grooves at a track pitch of 0.6 to 0.9 micrometer, the two layered members being bonded together with their respective recording layers on the inside to constitute a total thickness of 1.2±0.2 mm.

The above DVD-R optical information recording media can also be configured with a protective layer further provided the reflective layer.

The information recording medium of the present invention can be manufactured by the method described below, for example. The supports (including the protective support) may be selected as desired from among various materials that are conventionally employed as the supports of information recording media. Examples of these support materials are: glass; polycarbonate; polymethyl methacrylate, and other acrylic resins; polyvinyl chloride, vinyl chloride copolymers, and other vinyl chloride resins; epoxy resins; amorphous polyolefins; and polyesters. These may be employed in combination as desired. These materials can be employed as films or as rigid supports. Of these materials, polycarbonate is preferable the perspectives of moisture resistance, dimensional stability, cost and the like.

To enhance smoothness, increase adhesive strength, and prevent alteration of the recording layer, an undercoating layer may be provided on the surface of the support on the side on which the recording layer is provided. Examples of the material employed in the undercoating layer are: polymethyl methacrylate, acrylic acid—methacrylic acid copolymers, styrene—maleic anhydride copolymers, polyvinylalcohols, N-methylolacrylamide, styrene—vinyltoluene copolymers, chlorosulfonated polyethylene, nitrocellulose, polyvinyl chloride, chlorinated polyolefin, polyester, polyimide, vinyl acetate—vinyl chloride copolymers, ethylene—vinyl acetate copolymers, polyethylene, polypropylene, polycarbonates, and other polymeric materials; and surface-modifying agents such as silane coupling agents. The undercoating layer can be formed by dissolving or dispersing the above-described material in a suitable solvent to prepare a coating liquid, and coating this coating liquid to the surface of the support by a coating method such as spin coating, dip coating, or extrusion coating.

Tracking grooves or irregularities denoting information such as address signals, that are called pre-grooves, are formed on the support (or undercoating layer). The pre-grooves are preferably directly formed on the support at the above-stated track pitch in the course of injection molding or extrusion molding a resin material such as polycarbonate. The pre-grooves may also be formed by means of a layer having pre-grooves on its surface (referred to as “pre-groove layer”, hereinafter) separate from the support. A mixture of at least one monomer (or oligomer) selected from the group consisting of acrylic acid monoesters, diesters, triesters, and tetraesters, and a photopolymerization initiator may be employed as the material of the pre-groove layer. The pre-groove layer may be formed by, for example, first coating a mixed liquid comprised of the above acrylic acid ester and polymerization initiator on a precision-crafted matrix (stamper), positioning the support on this coating liquid layer, irradiating ultraviolet radiation through the support or matrix to cure the coating layer and tightly bond the support and the coating layer, and separating the support from the matrix.

A recording layer containing the above-described dye can be provided on the surface of the support (or undercoating layer) on which the pre-grooves are formed. The depth of the pre-grooves is preferably equal to or greater than 140 nm. A pre-groove with a depth of equal to or greater than 140 nm can increase the barrier between pre-grooves, reduce recording mark interference (crosstalk) between adjacent tracks, and yield a good recording signal. The depth of the pre-grooves more preferably falls within a range of 145 to 165 nm. A depth of equal to or greater than 145 nm can further increase the effect of reducing crosstalk, and at equal to or lower than 165 nm, good reflectance can be achieved.

Various anti-fading agents can be incorporated in the recording layer to enhance light resistance. Examples of typical anti-fading agents are the metal complexes, diimmonium salts, and aminium salts denoted by general formulas (III), (IV), and (V) described in Japanese Unexamined Patent Publication (KOKAI) Heisei No. 3-224793, which is expressly incorporated herein by reference in its entirety; the nitroso compounds disclosed in Japanese Unexamined Patent Publication (KOKAI) Heisei Nos. 2-300287 and 2-300288, which are expressly incorporated herein by reference in their entirety; and the TCNQ derivatives disclosed in Japanese Unexamined Patent Publication (KOKAI) Heisei No. 10-151861, which is expressly incorporated herein by reference in its entirety.

The recording layer can be formed by dissolving the above-described dye, and as desired, a quencher, binder, or the like, in a suitable solvent to prepare a coating liquid; coating the coating liquid to the support surface to form a coating; and drying the coating. Examples of the solvent employed in the coating liquid to form the recording layer are: esters such as butyl acetate, ethyl lactate, and 2-methoxyethyl acetate; ketones such as methyl ethyl ketone, cyclohexanone, and methyl isobutyl ketone; chlorinated hydrocarbons such as dichloromethane, 1,2-dichloroethane, and chloroform; amides such as dimethylformamide; hydrocarbons such as cyclohexane; alkyl ethers such as tetrahydrofuran, ethylether, and dioxane; alcohols such as ethanol, n-propanol, isopropanol, n-butanol, and diacetone alcohol; fluorine-based solvents such as 2,2,3,3-tetrafluoropropanol; and glycol ethers such as ethylene glycol monomethyl ether, ethylene glycol monoethyl ether, and propylene glycol monomethyl ether. These solvents can be employed singly or on combinations of two or more taking into account the solubility of the dye employed. Based on the objective, additives such as antioxidants, UV-absorbing agents, plasticizers, and lubricants can also be added as needed to the coating liquid.

Examples of the binder are natural organic polymeric substances such as gelatins, cellulose derivatives, dextran, rosin, and rubber; and synthetic organic polymers such as the initial condensation products of thermosetting resins such as hydrocarbon-based resins such as polyethylene, polypropylene, polystyrene, and polyisobutylene, vinyl-based resins such as polyvinyl chloride, polyvinylidene chloride, and polyvinyl chloride—polyvinyl acetate copolymers, acrylic resins such as polymethyl acrylate and polymethyl methacrylate, polyvinyl alcohols, chlorinated polyethylene, epoxy resin, butyral resin, rubber derivatives, and phenol formaldehyde resins. When employing a binder as a material in the recording layer, the quantity of binder employed generally ranges from 0.01 to 50-fold (by weight), and preferably ranges from 0.1 to 5-fold (by weight), the quantity of the dye. The concentration of dye in the coating liquid thus prepared generally falls within a range of 0.01 to 10 weight percent, preferably a range of 0.1 to 5 weight percent.

Examples of the coating method employed are spraying, spin-coating, dipping, roll coating, blade coating, the doctor roll method, and screen printing. The recording layer may comprise a single layer or multiple layers. When a recording layer comprised of two or more layers is present in the optical information recording medium of the present invention, the dye having a film-softening temperature of equal to or higher than 290° C. may be contained in just one layer of the recording layer, two or more layers of the recording layer, or all layers of the recording layer. The thickness of the recording layer (of each recording layer when there are multiple recording layers) generally ranges from 20 to 500 nm, and preferably ranges from 50 to 300 nm.

A reflective layer is normally provided on the above-described recording layer to enhance reflectance during the reproduction of information. The light reflective substance employed as the material of the reflective layer is a substance with a high reflectance for the laser beam. Examples are: Mg, Se, Y, Ti, Zr, Hf, V, Nb, Ta, Cr, Mo, W, Mn, Re, Fe, Co, Ni, Ru, Rh, Pd, Ir, Pt, Cu, Ag, Au, Zn, Cd, Al, Ga, In, Si, Ge, Te, Pb, Po, Sn, Bi, and other metals, semimetals, and stainless steel. Of these, Cr, Ni, Pt, Cu, Ag, Au, Al, and stainless steel are preferable, and Ag is more preferable. These substances may be employed singly or in combinations of two or more. They may also be employed in the form of alloys. The reflective layer can be formed, for example, by vapor depositing, sputtering, or ion plating the above reflective substance on the recording layer. The thickness of the reflective layer normally falls within a range of 10 to 300 nm, preferably a range of 50 to 200 nm.

A protective layer can be provided on the reflective layer to physically and chemically protect the recording layer and the like. This protective layer can also be provided on the side of the support on which no recording layer is formed to enhance scratch resistance and moisture resistance. Examples of the material employed in the protective layer are inorganic substances such as SiO, SiO₂, MgF₂, SnO₂, and Si₃N₄; and organic substances such as thermoplastic resins, thermosetting resins, and UV-curable resins. The protective layer can be formed, for example, by laminating a film obtained by a plastic extrusion process on the reflective layer and/or support with an adhesive layer. It can also be provided by a method such as vacuum vapor deposition, sputtering, or coating. A thermoplastic resin or thermosetting resin can be dissolved in a suitable solvent to prepare a coating liquid and the coating liquid can be applied and dried to form a protective layer. A UV-curable resin can be used as is, or dissolved in a suitable solvent to prepare a coating liquid; the coating liquid is then applied and cured by irradiation of UV radiation to form a protective layer. Various additives such as antistatic agents, antioxidants, and UV-absorbing agents can be added to the coating liquid based on the objective. The thickness of the protective layer generally falls within a range of 0.1 to 100 micrometers. A layered member comprising on a support a recording layer and reflective layer, and, as needed, a protective layer, can be prepared by the above steps. By fabricating two layered members in the above-described manner and bonding them together with an adhesive with their respective recording layers on the inside, it is possible to manufacture a DVD-R information recording medium having two recording layers. The layered member obtained and a round protective support of roughly the same dimensions as the support of the layered member can be bonded with an adhesive with the recording layer on the inside to manufacture a DVD-R information recording medium having a recording layer on just one side.

Information can be recorded on the optical information recording medium of the present invention.

A recording laser beam such as a semiconductor laser beam is first irradiated from the support side while rotating the information recording medium at a constant linear speed or constant angular speed. Irradiation of this beam is thought to form voids at the interface between the recording layer and the reflective layer (the voids are formed by deformation of the recording layer or reflective layer, or by deformation of both layers), cause the support to undergo a deformation buildup, discolor the recording layer, change its associative state, or the like, thereby changing the refractive index and thus recording information. The optical information recording medium of the present invention has good high-speed recording characteristics. For example, even when recording information at a linear recording velocity of equal to or higher than 27.9 m/s, preferably 41.8 to 55.8 m/s, the increase in jitter due to thermal interference can be suppressed and high recording characteristics can be achieved. For example, a semiconductor laser beam having an oscillation wavelength falling within a range of 600 to 700 nm (preferably 620 to 680 nm, more preferably 630 to 660 nm) can be employed as the recording beam for DVD-Rs. The information recorded in the manner set forth above can be reproduced by irradiating the optical information recording medium from the support side with a semiconductor laser beam having the same wavelength as that employed during recording while rotating the optical information recording medium at the same constant linear speed as above, and detecting the reflected light.

The present invention further relates to a method of recording information on the recording layer comprised in the optical information recording medium of the present invention by irradiation of a laser beam onto the optical information recording medium. As set forth above, the optical information recording medium of the present invention can achieve good recording characteristics by suppressing jitter even during high-speed recording, such as at a linear recording velocity of equal to or higher than 27.9 m/s, or even 41.8 to 55.8 m/s.

### EXAMPLES

The present invention will be described in detail below based on examples. However, the present invention is not limited to the examples.

### Synthesis Example 1

Dye D-5 was synthesized by the following synthesis method.

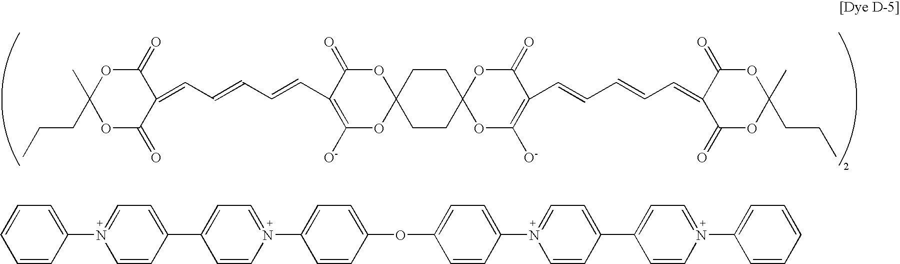

(1) Synthesis of Hydrochloride of Cation Compound

Synthesis was conducted by the following scheme:

(i) Synthesis of Intermediate A

To a solution of 15 g of 4,4′-bipyridyl in 100 mL of acetone was added 13.2 g of 1-chloro-2,4-dinitrobenzene. The mixture was stirred for 15 minutes at room temperature and then hot refluxed for 15 hours. When the reaction had ended, the mixture was allowed to cool to room temperature and the precipitating crystals were recovered by filtration under reduced pressure. Finally, the crystals obtained were washed with acetone and dried, yielding 18.8 g of intermediate A.

(ii) Synthesis of Intermediate B

To a suspension of 14.4 g of intermediate A in 100 mL of acetonitrile was added 4.6 g of aniline and the mixture was hot refluxed for 7 hours. When the reaction had ended, the mixture was allowed to cool to room temperature, and the precipitating crystals were recovered by filtration. The crystals were then washed with acetonitrile and dried. 20 mL of methanol was added to the crude crystals obtained, which were then fully dissolved by heating. To this solution was added 200 mL of ethyl acetate and the mixture was stirred for 1 hour at room temperature. The crystals obtained were recovered by filtration, yielding 10.4 g of intermediate B.

(iii) Synthesis of Intermediate C

5 mL of N-methylpyrrolidone was added to 3 g of intermediate B and 7 g of 1-chloro-2,4-dinitrobenzene, and the mixture was heated for 9 hours in an oil bath with an external temperature of 110° C. When the reaction had ended, the mixture was allowed to cool to room temperature. The precipitating crystals were recovered by filtration, washed with N-methylpyrrolidone, washed with ethyl acetate, and dried, yielding 3.7 g of intermediate C.

(iv) Synthesis of Hydrochloride Salt of Cation Compound

To a suspension of 2.4 g of intermediate C in 30 mL of dimethylformamide was added 0.4 g of 4,4′-diaminodiphenylether and the mixture was stirred with heating for 6 hours at 100° C. When the reaction had ended, the mixture was allowed to cool to room temperature and the precipitating crystals were recovered by filtration. The crystals were washed with dimethylformamide, washed with ethyl acetate, and dried, yielding 1.16 g of a hydrochloride salt of cation compound II-5.

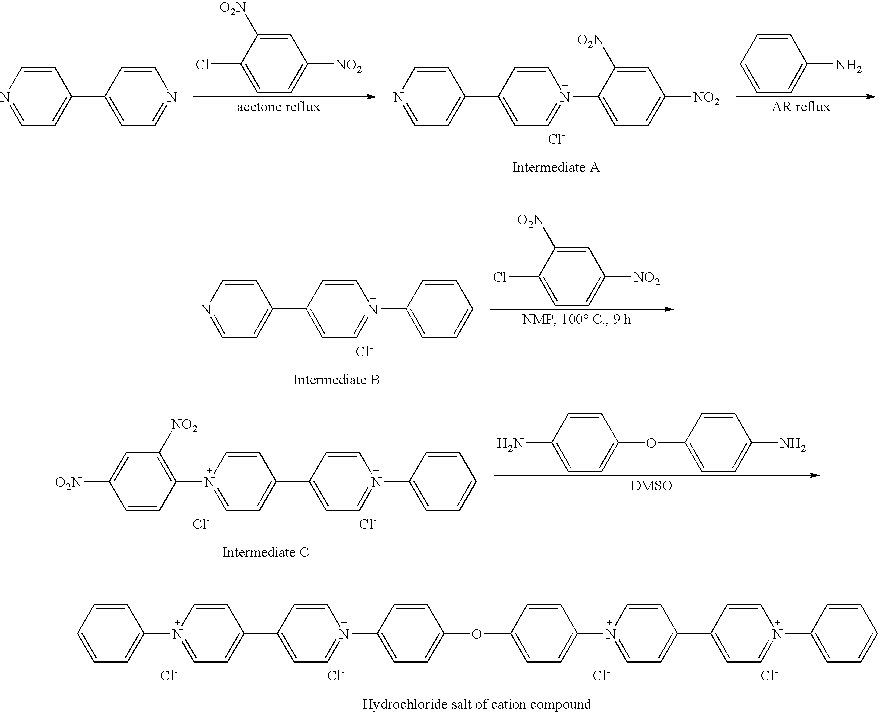

¹H-NMR data of the above cation compound II-5 (CD₃OD): 9.62-9.56 (m, 8H), 8.97-8.83 (m, 8H), 8.10-8.06 (m, 4H), 7.97-7.94 (m, 4H), 7.83-7.80 (m, 6H), 7.57-7.53 (m, 4H)

(2) Synthesis of Dye D-5 (Salt Formation)

A 1.0 g of the hydrochloride of cation compound II-5 obtained above was dissolved with heating in 30 mL of methanol. To this solution was added 3.1 g of the dye starting material indicated below and the mixture was stirred for 30 min at 60° C. After cooling, the mixture was stirred for 2 hours at room temperature. The precipitating crystals were recovered by filtration, washed with methanol, and dried, yielding 1.8 g of dye D-5 (absorption λmax=561.8 nm, ε=6.07×10⁵/2,2,3,3-tetrafluoropropanol (TFP)).

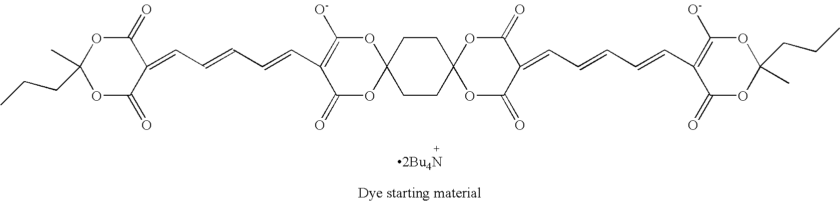

¹H-NMR data of dye D-5 (d⁶-DMSO): 9.70 (s(br), 8H), 9.08 (s(br), 8H), 8.08 (s(br), 4H), 7.98 (s(br), 4H), 7.81 (s(br), 6H), 7.70-7.46 (m, 16H), 7.20-7.08 (m, 8H), 1.99 (s, 16H), 1.80-1.75 (m, 8H), 1.52 (s, 12H), 1.47-1.32 (m, 8H), 0.88 (t, 12H)

### Synthesis Example 2

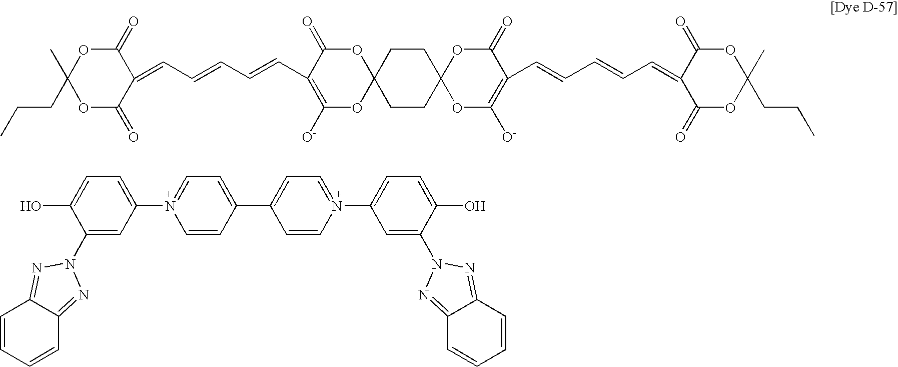

Dye D-57 was synthesized according to the following scheme by the method described in Japanese Unexamined Patent Publication (KOKAI) No. 2002-59652, which is expressly incorporated herein by reference in its entirety (absorption λmax=561.7 nm, ε=3.15×10⁵/2,2,3,3-tetrafluoropropanol (TFP)).

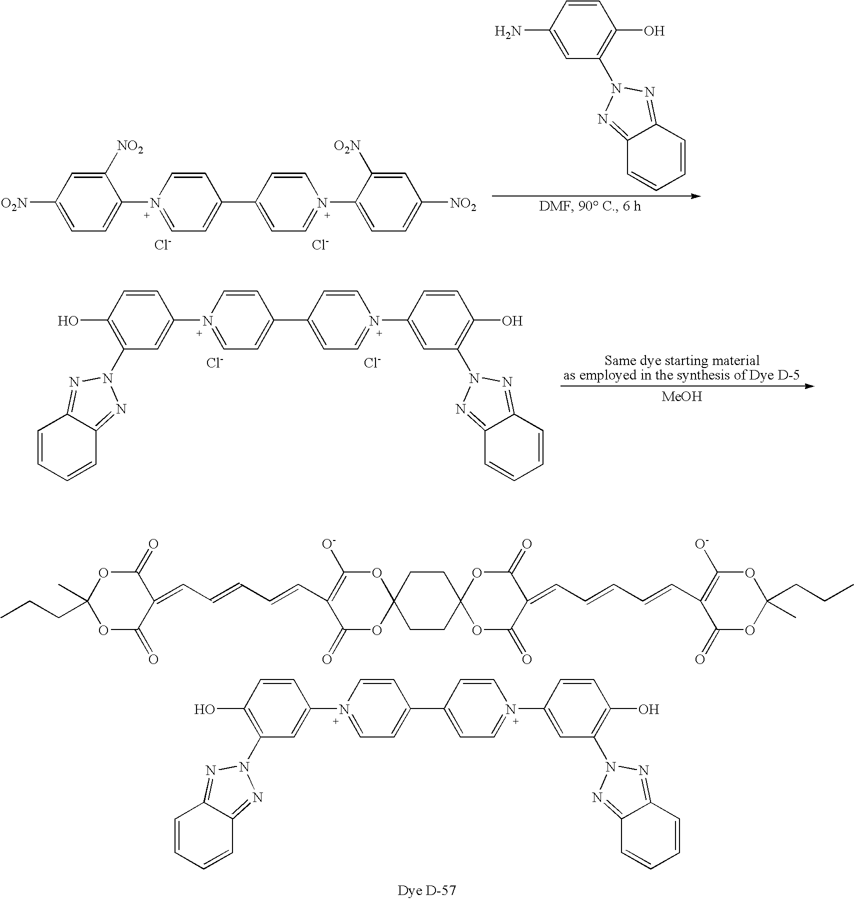

¹H-NMR data of dye D-57 (d⁶-DMSO): 11.57 (s, 2H), 9.72 (d, 4H), 9.07 (d, 4H), 8.52 (s, 2H), 8.03-8.10 (m, 6H), 7.48-7.71 (m, 12H), 7.10-7.21 (m, 4H), 2.00 (s, 8H), 1.76-1.81 (m, 4H), 1.53 (s, 6H), 1.33-1.47 (m, 4H), 0.88 (t, 6H)

### Measurement of Film-Softening Temperature

The film-softening temperature of dyes D-5 and D-57, as well as dyes 1 and 2, described further below, were measured by the method given below. The film-softening temperatures that were measured are given in Table 2.

(Method of Measuring Film-Softening Temperature)

A 20 mg quantity of dye was dissolved in 1 mL of tetrafluoropropanol. This solution was coated to a glass support by spin coating (coating conditions: 24° C., rotational speed 100 rpm) to form a coating film 300 nm in thickness for use in measuring the film-softening temperature. Next, using a model 2990 microthermal analyzer (μTA) made by TA Instruments, the temperature at which a needle began to enter the coating film while raising the temperature was measured, and this temperature was adopted as the film-softening temperature.

### Example 1

### Manufacture of Optical Information Recording Medium

Polycarbonate resin was injection molded to form a support with a diameter of 120 mm, a thickness of 0.600 mm, and spiral grooves (depth: 140 nm, groove width: 365 nm, track pitch: 0.74 micrometer). This support was employed to form a recording layer. A coating liquid comprised of a solution of 1.00 g of dye D-5 in 100 mL of 2,2,3,3-tetrafluoropropanol was prepared. This coating solution was coated by spin coating to the surface of the support on which the grooves had been formed to form a dye layer. Next, AgNdCu alloy (target composition: Ag 98.4 atom percent, Nd 0.7 atom percent, Cu 0.9 atom percent) was sputtered onto the dye layer to form a reflective layer 120 nm in thickness. The surface of the above disk on the reflective layer side and a separately prepared polycarbonate resin support 120 mm in diameter and 0.600 mm in thickness were bonded with an adhesive in the form of a UV-curable resin (Daicure Clear SD640 made by Dainippon Ink and Chemicals, Inc.) to manufacture a DVD-R optical information recording medium.

### Example 2

### Comparative Examples 1 and 2

DVD-R optical information recording media were manufactured by the same method as in Example 1 with the exception that dye D-5 was replaced with dyes D-57, 1, and 2, respectively. Dye 1 was synthesized according to the synthesis method of dye D-57, and dye 2 was synthesized by the method described in Japanese Unexamined Patent Publication (KOKAI) No. 2004-188968, which is expressly incorporated herein by reference in its entirety.

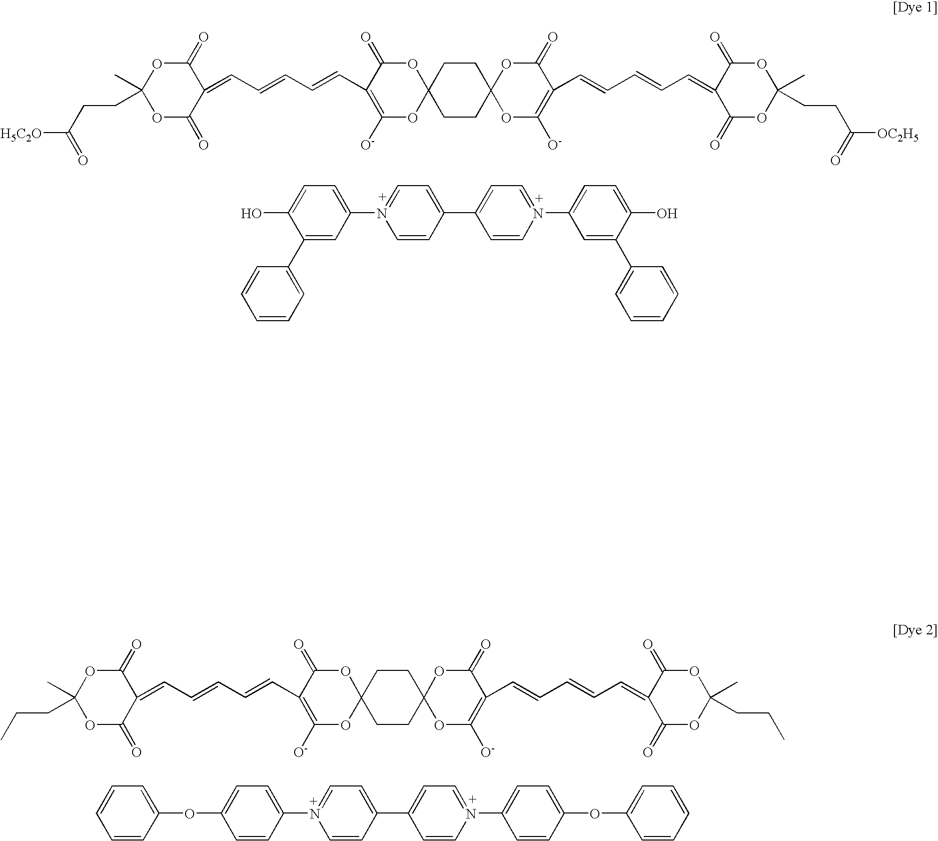

### Evaluation of Optical Information Recording Media

Using a DDU-1000 and a multisignal generator (made by Pulstec Industrial Co., Ltd., laser wavelength 655.9 nm, object lens numerical aperture 0.65), the linear velocity was set to 41.88 m/s and an 8-16 modulated signal was recorded. The 12× recording-use strategy described in DVD+R 4.7 GB Basic Format Specifications Version 3.0 was employed, with settings made as per the various parameters set forth in Table 1. Recording was conducted with 10 stages of variation centered on the optimal recording power. Reproduction was then conducted at a linear velocity of 3.49 m/s. A time interval analyzer TA320 (made by Yokogawa Electric Corp.) was used on the reproduced signal to measure the jitter and the average 3T space length and average 14T space length at an asymmetry of 0. The recording power width at which the jitter was less than 9 percent divided by the average power level was adopted as the power margin. At power margins of equal to or greater than 0.1, the jitter did not exceed the permissible range and there was no impediment to reproduction, even when the power of the recording device fluctuated during actual use. The results are given in Table 2.

TABLE 1

| | |
|---|---|
| T13 | 2.938 |
| Ttop | 1.500 |
| T1p (4T) | 0.937 |
| (5T) | 1.200 |
| dT1e (3T) | 0.125 |
| Tc | 2.000 |

TABLE 2

| | Dye in | Average 3 T | | |
|---|---|---|---|---|
| | the | space length/ | | Film-softening |
| | recording | average 14 T | Power | temperature |
| | layer | space length | margin | (° C.) |
| Example 1 | D-5 | 0.219 | 0.16 | 300 |
| Example 2 | D-57 | 0.217 | 0.14 | 296 |
| Comp. | Dye 1 | 0.211 | 0.09 | 285 |
| Ex.1 | | | | |
| Comp. | Dye 2 | 0.201 | 0.01 | 262 |
| Ex.2 | | | | |

### Evaluation Results

As shown in Table 2, the use of a dye with a film-softening temperature of equal to or higher than 290° C. in the recording layer yielded an optical information recording medium with a high power margin and an average 3T space length/average 14T space length that was greater than 0.211.

The present invention can provide an optical information recording medium that achieves good recording characteristics and suppresses jitter even during high-speed recording.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

Unless otherwise stated, a reference to a compound or component includes the compound or component by itself, as well as in combination with other compounds or components, such as mixtures of compounds.

As used herein, the singular forms “a,” “an,” and “the” include the plural reference unless the context clearly dictates otherwise.

Except where otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not to be considered as an attempt to limit the application of the doctrine of equivalents to the scope of the claims, each numerical parameter should be construed in light of the number of significant digits and ordinary rounding conventions.

Additionally, the recitation of numerical ranges within this specification is considered to be a disclosure of all numerical values and ranges within that range. For example, if a range is from about 1 to about 50, it is deemed to include, for example, 1, 7, 34, 46.1, 23.7, or any other value or range within the range.

What is claimed is:

1. An optical information recording medium comprising a recording layer on a support, wherein
the recording layer comprises a dye having a film-softening temperature of equal to or higher than 290° C.

2. The optical information recording medium according to claim 1, wherein the dye is a dye denoted by general formula (I). 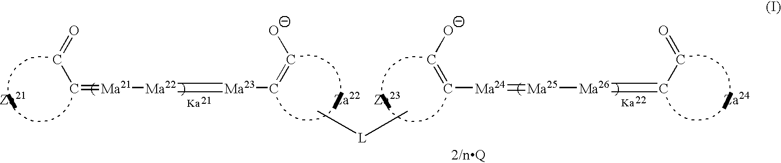
In general formula (I), Za²¹, Za²², Za²³, and Za²⁴ each independently denote an atom group forming an acid nucleus, Ma²¹, Ma²², Ma²³, Ma²⁴, Ma²⁵, and Ma²⁶ each independently denote a substituted or unsubstituted methine group, L denotes a divalent linking group that does not form a π-conjugated system with two bonds, Ka²¹ and Ka²² each independently denote an integer ranging from 0 to 3, and Q denotes a cation of valence n, and n denotes an integer ranging from 1 to 6. When Ka²¹ denotes 2 or 3, plural Ma²¹ and plural Ma²² present may be respectively identical or different from each other; and when Ka²² denotes 2 or 3, plural Ma²⁵ and plural Ma²⁶ present may be respectively identical or different from each other.

3. The optical information recording medium according to claim 2, wherein Q in general formula (I) denotes a quadrivalent cation denoted by general formula (II). 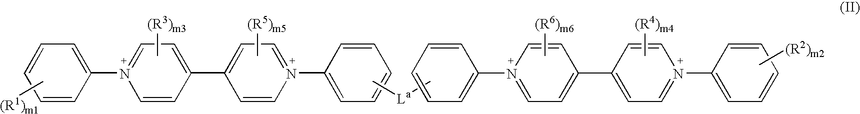
In general formula (II), R¹, R², R³, R⁴, R⁵, and R⁶ each independently denote a substituent, m1 and m2 each independently denote an integer ranging from 0 to 5, m3, m4, m5, and m6 each independently denote an integer ranging from 0 to 4, L^{a} denotes a divalent linking group. When m1 denotes an integer ranging from 2 to 5, plural R¹ present may be identical or different from each other; when m2 denotes an integer ranging from 2 to 5, plural R² present may be identical or different from each other; when m3 denotes an integer ranging from 2 to 4, plural R³ present may be identical or different from each other; when m4 denotes an integer ranging from 2 to 4, plural R⁴ present may be identical or different from each other; when m5 denotes an integer ranging from 2 to 4, plural R⁴ present may be identical or different from each other; and when m6 denotes an integer ranging from 2 to 4, plural R⁶ present may be identical or different from each other.

4. The optical information recording medium according to claim 2, wherein Q in general formula (I) denotes a divalent cation denoted by general formula (III). 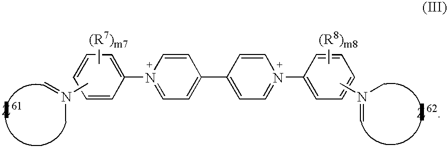
In general formula (III), Z⁶¹ and Z⁶² each independently denote an atom group forming a nitrogen-containing heteroaryl ring, R⁷ and R⁸ each independently denote a substituent, and m7 and m8 each independently denote an integer ranging from 0 to 4. When m7 denotes an integer ranging from 2 to 4, plural R⁷ present may be identical or different from each other; and when m8 denotes in integer ranging from 2 to 4, plural R⁸ present may be identical or different from each other.

5. The optical information recording medium according to claim 1, wherein the recording layer satisfies Equation (1) when an EFM signal is recorded in a random pattern at a linear recording velocity of 41.88 m/s:
Average 3T space length/average 14T space length>0.211 (1)

6. The optical information recording medium according to claim 1, wherein the support has a pregroove with a groove depth of equal to or higher than 140 nm on a surface facing the recording layer.

7. The optical information recording medium according to claim 1, wherein information is recorded on the recording layer at a linear recording velocity of equal to or higher than 27.9 m/s.

8. A method of recording information on the recording layer comprised in the optical information recording medium of claim 1 by irradiation of a laser beam onto the optical information recording medium.

9. The method of recording information according to claim 8, wherein the information is recorded at a linear recording velocity of equal to or higher than 27.9 m/s.

10. The method of recording information according to claim 8, wherein the dye is a dye denoted by general formula (I). 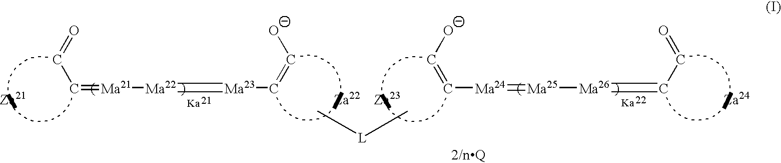
In general formula (I), Za²¹, Za²², Za²³, and Za²⁴ each independently denote an atom group forming an acid nucleus, Ma²¹, Ma²², Ma²³, Ma²⁴, Ma²⁵, and Ma²⁶ each independently denote a substituted or unsubstituted methine group, L denotes a divalent linking group that does not form a π-conjugated system with two bonds, Ka²¹ and Ka²² each independently denote an integer ranging from 0 to 3, and Q denotes a cation of valence n, and n denotes an integer ranging from 1 to 6. When Ka²¹ denotes 2 or 3, plural Ma²¹ and plural Ma²² present may be respectively identical or different from each other; and when Ka²² denotes 2 or 3, plural Ma²⁵ and plural Ma²⁶ present may be respectively identical or different from each other.

11. The method of recording information according to claim 10, wherein Q in general formula (I) denotes a quadrivalent cation denoted by general formula (II). 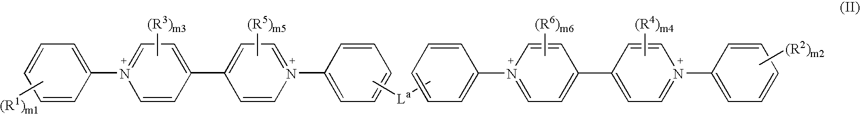
In general formula (II), R¹, R², R³, R⁴, R⁵, and R⁶ each independently denote a substituent, m1 and m2 each independently denote an integer ranging from 0 to 5, m3, m4, m5, and m6 each independently denote an integer ranging from 0 to 4, L^{a} denotes a divalent linking group. When m1 denotes an integer ranging from 2 to 5, plural R¹ present may be identical or different from each other; when m2 denotes an integer ranging from 2 to 5, plural R² present may be identical or different from each other; when m3 denotes an integer ranging from 2 to 4, plural R³ present may be identical or different from each other; when m4 denotes an integer ranging from 2 to 4, plural R⁴ present may be identical or different from each other; when m5 denotes an integer ranging from 2 to 4, plural R⁴ present may be identical or different from each other; and when m6 denotes an integer ranging from 2 to 4, plural R⁶ present may be identical or different from each other.

12. The method of recording information according to claim 10, wherein Q in general formula (I) denotes a divalent cation denoted by general formula (III). 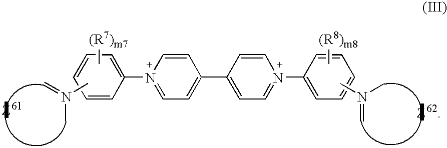
In general formula (III), Z⁶¹ and Z⁶² each independently denote an atom group forming a nitrogen-containing heteroaryl ring, R⁷ and R⁸ each independently denote a substituent, and m7 and m8 each independently denote an integer ranging from 0 to 4. When m7 denotes an integer ranging from 2 to 4, plural R⁷ present may be identical or different from each other; and when m8 denotes in integer ranging from 2 to 4, plural R⁸ present may be identical or different from each other.

13. The optical information recording medium according to claim 8, wherein the recording layer satisfies Equation (1) when an EFM signal is recorded in a random pattern at a linear recording velocity of 41.88 m/s:
Average 3T space length/average 14T space length>0.211 (1)
